(19) United States
(12) Patent Application Publication
(10) Pub. No.: US 2026/0047179 A1
(43) Pub. Date: Feb. 12, 2026

(54) MULTI-THRESHOLD VOLTAGE INTEGRATION SCHEMES FOR SEMICONDUCTOR DEVICES

(71) Applicant: Applied Materials, Inc., Santa Clara, CA (US)

(72) Inventors: Srinivas Gandikota, Santa Clara, CA (US); Hsin-Jung Yu, Santa Clara, CA (US); Geetika Bajaj, Cupertino, CA (US); Tuerxun Ailihumaer, Santa Clara, CA (US); Seshadri Ganguli, San Jose, CA (US); Sonia Kaur Chimni, San Jose, CA (US); Dhruvika Randad, Cupertino, CA (US)

(73) Assignee: Applied Materials, Inc., Santa Clara, CA (US)

(21) Appl. No.: 19/361,727

(22) Filed: Oct. 17, 2025

Related U.S. Application Data
(63) Continuation-in-part of application No. 18/198,064, filed on May 16, 2023.
(60) Provisional application No. 63/343,051, filed on May 17, 2022.

(51) Int. Cl. H10D 84/01; H10D 84/83

(52) U.S. Cl. CPC H10D 84/0144; H10D 84/8314

(57) ABSTRACT

Multiple threshold voltage (Multi-Vₜ) integration schemes for semiconductor devices are described. The methods include the use of diffusion barrier layers configured to provide multi-Vₜ through controlled dopant diffusion.

### CROSS-REFERENCE TO RELATED APPLICATIONS

This application is a continuation-in-part of U.S. patent application Ser. No. 18/198,064, filed May 16, 2023, which claims priority to U.S. Provisional Application Ser. No. 63/343,051 filed May 17, 2022, which are herein incorporated by reference in their entireties.

### BACKGROUND

### Field

Embodiments of the present disclosure relate to a method of processing substrates and, more specifically, to adjusting threshold voltages of portions of a field-effect-transistor (FET) device by forming an electrostatic dipole layer and adjusting a thickness of a diffusion barrier layer between the dipole layer and a gate dielectric layer.

### Description of the Related Art

Semiconductor devices, such as an integrated circuit (IC), generally have electronic circuit elements, such as transistors, diodes, and resistors, fabricated integrally on a single body of semiconductor material. The various circuit elements are connected through conductive connectors to form a complete circuit, which can contain millions of individual circuit elements. Advances in semiconductor materials and processing techniques have resulted in reducing the overall size of the IC while increasing the number of circuit elements. Additional miniaturization is highly desirable for improved IC performance and cost reduction. Control of a threshold voltage (Vₜ) of transistors is important for use in various devices including gate modules and can be a challenge as gate lengths shrink.

Therefore, there is a need for methods of forming structures in FET devices and modulating threshold voltage (Vₜ) in different regions of the FET devices.

### SUMMARY

Embodiments of the present disclosure provide a method of adjusting a threshold voltage in a field-effect-transistor (FET) device. The method includes performing a deposition process to deposit a diffusion barrier layer over a gate dielectric layer in a first region, a second region, and a third region of a semiconductor structure, performing a first patterning process to remove a portion of the deposited diffusion layer in the first region, performing a second patterning process to partially remove a portion of the deposited diffusion barrier layer in the second region, performing a dipole layer deposition process to deposit a dipole layer over the gate dielectric layer in the first region, and the diffusion barrier layer in the second region and in the third region, and performing an annealing process to drive dipole dopants from the dipole layer into the gate dielectric layer.

Embodiments of the present disclosure provide a method of adjusting a threshold voltage in a field-effect-transistor (FET) device. The method includes forming a diffusion barrier layer on a gate dielectric layer, the diffusion barrier layer having a varying thickness in a first region, a second region, and a third region of a semiconductor structure, and performing a precision material engineering (PME) process on exposed surfaces of the semiconductor structure.

Embodiments of the present disclosure provide a method of forming a p-type field-effect-transistor (PFET) device and an n-type field-effect transistor (NFET) device. The method includes forming a first n-type dipole layer on a first gate dielectric layer formed on a silicon-germanium containing layer, the first n-type dipole layer having a varying thickness in a first region, a second region and a third region of a PFET device, forming a second n-type dipole layer on a second gate dielectric layer, the second n-type dipole layer having a varying thickness in a first region, a second region, and a third region of an NFET device, and performing an annealing process to drive dipole dopants from the first n-type dipole layer into the first gate dielectric layer and from the second n-type dipole layer into the second gate dielectric layer.

Embodiments of the present disclosure provide a method comprising: forming at least one diffusion barrier layer directly on a first high-κ dielectric layer directly on an interfacial layer of a semiconductor structure having a plurality of regions; forming at least one dipole layer directly on the at least one diffusion barrier layer in each of the plurality of regions; forming at least one capping layer directly on the at least one dipole layer; performing a first rapid thermal process (RTP) to drive atoms from the at least one dipole layer into an interface between the first high-κ dielectric layer and the interfacial layer in each of the plurality of regions; removing the at least one capping layer, the at least one dipole layer, and the at least one diffusion barrier layer in each of the plurality of regions to expose a top surface of the first high-κ dielectric layer; depositing a second high-κ dielectric layer directly on the top surface of the first high-κ dielectric layer in each of the plurality of regions; performing a second RTP in each of the plurality of regions; and depositing at least one metal gate film directly on the second high-κ dielectric layer in each of the plurality of regions to form multiple threshold voltages (multi-Vₜ) including a different threshold voltage (Vₜ) in each of the plurality of regions of the semiconductor structure.

Embodiments of the present disclosure provide a method comprising: forming a first diffusion barrier layer directly on a first high-κ dielectric layer directly on an interfacial layer of a semiconductor structure having a first region, a second region, and a third region, the first diffusion barrier layer formed on the first region; forming a first dipole layer directly on the first diffusion barrier layer; forming a capping layer directly on the first dipole layer; performing a first rapid thermal process (RTP) to drive atoms from the first dipole layer into an interface between the first high-κ dielectric layer and the interfacial layer in the first region; removing the capping layer, the first dipole layer, and the first diffusion barrier layer in the first region to expose a top surface of the first high-κ dielectric layer; depositing a second high-κ dielectric layer directly on the top surface of the first high-κ dielectric layer in the first region; performing a second RTP; and depositing at least one metal gate film directly on the second high-κ dielectric layer to form a first threshold voltage (Vₜ) in the first region.

Embodiments of the present disclosure provide a processing system comprising: a first transfer module and a second transfer module, each of the first transfer module and the second transfer module independently comprising a substrate handling robot configured to move at least one substrate; a plurality of process chambers, wherein the substrate handling robot of the first transfer module is configured to transfer the at least one substrate between some of the process chambers and the substrate handling robot of the second transfer module is configured to transfer the at least one substrate between some of the process chambers; and a system controller configured to process the at least one substrate, and the system controller configured to perform a method comprising: forming at least one diffusion barrier layer directly on a first high-κ dielectric layer directly on an interfacial layer of a semiconductor structure having a plurality of regions; forming at least one dipole layer directly on the at least one diffusion barrier layer in each of the plurality of regions; forming at least one capping layer directly on the at least one dipole layer; performing a first rapid thermal process (RTP) to drive atoms from the at least one dipole layer into an interface between the first high-κ dielectric layer and the interfacial layer in each of the plurality of regions; removing the at least one capping layer, the at least one dipole layer, and the at least one diffusion barrier layer in each of the plurality of regions to expose a top surface of the first high-κ dielectric layer; depositing a second high-κ dielectric layer directly on the top surface of the first high-κ dielectric layer in each of the plurality of regions; performing a second RTP in each of the plurality of regions; and depositing at least one metal gate film directly on the second high-κ dielectric layer in each of the plurality of regions to form multiple threshold voltages (multi-Vₜ) including a different threshold voltage (Vₜ) in each of the plurality of regions of the semiconductor structure.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIGS. 1A, 1B, and 1C depict a perspective view of a substrate and cross-sectional views of transistors disposed on the substrate, according to some embodiments.

FIG. 2 illustrates a processing system that can be used to perform one or more of the processes described herein.

FIG. 3 depicts a process flow diagram of a method for processing a substrate, according to some embodiments.

FIG. 4 depicts a substrate having a plurality of regions, according to some embodiments.

FIG. 5 depicts a process flow diagram of a method for processing a substrate, according to some embodiments.

FIG. 6 depicts a p-type field-effect-transistor (PFET) device, according to some embodiments.

FIG. 7 depicts an n-type field-effect transistor (NFET) device, according to some embodiments.

FIG. 8 depicts a PFET device, according to some embodiments.

FIG. 9 depicts a PFET device, according to some embodiments.

FIG. 10 depicts an NFET device, according to some embodiments.

FIG. 11 depicts a process flow diagram of a method for processing a substrate, according to some embodiments.

FIG. 12 depicts a perspective view of a semiconductor structure including a substrate and cross-sectional views of transistors disposed on the substrate, according to some embodiments.

FIG. 13 depicts a perspective view of a semiconductor structure including a substrate and cross-sectional views of transistors disposed on the substrate, according to some embodiments.

FIG. 14 depicts a perspective view of a semiconductor structure including a substrate and cross-sectional views of transistors disposed on the substrate, according to some embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of ±15%, or less, of the numerical value. For example, a value differing by ±14%, ±10%, ±5%, ±2%, or ±1%, would satisfy the definition of about.

Spatially relative terms, such as “beneath,” “below,” “lower,” “above,” “upper” and the like, may be used herein for ease of description to describe one element's relationship to another element(s) or feature(s) as illustrated in the Figures. It will be understood that the spatially relative terms are intended to encompass different orientations of the structure (e.g., substrate) in use or operation in addition to the orientation depicted in the Figures. For example, if the substrate in the Figures is turned over, elements described as “below” or “beneath” other elements would then be oriented “above” the other elements. Thus, the exemplary term “below” may encompass both an orientation of above and below. The substrate may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein.

All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments,” “some embodiments,” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in some embodiments,” “in one embodiment,” or “in an embodiment” in various places throughout this specification are not necessarily referring to the same embodiment of the disclosure. In one or more embodiments, the particular features, structures, materials, or characteristics are combined in any suitable manner.

As used in this specification and the appended claims, the term “substrate” and “wafer” are used interchangeably, both referring to a surface, or portion of a surface, upon which a process acts. It will also be understood by those skilled in the art that reference to a substrate can also refer to only a portion of the substrate, unless the context clearly indicates otherwise. Additionally, reference to “depositing on” or “forming on” a substrate can mean both a bare substrate and a substrate with one or more films or features deposited or formed thereon.

A “substrate” or “substrate surface”, as used herein, refers to any portion of a substrate or portion of a material surface formed on a substrate upon which film processing is performed. In some embodiments, the substrate includes a patterned flat substrate.

For example, a substrate surface on which processing can be performed includes materials such as silicon, silicon oxide, silicon nitride, doped silicon, germanium, gallium arsenide, glass, sapphire, and any other materials such as metals, metal nitrides, metal alloys, and other conductive materials, depending on the application.

In some embodiments, the substrate includes at least one conductive material and at least one dielectric material.

Substrates can include, without limitation, semiconductor substrates/semiconductor materials. In some embodiments, the semiconductor substrate comprises one or more of doped or undoped crystalline silicon (Si), doped or undoped crystalline silicon germanium (SiGe), doped or undoped amorphous silicon (Si), or doped or undoped amorphous silicon germanium (SiGe).

Substrates may be exposed to a pre-treatment process to, for example, polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate. Substrates may have various dimensions, such as 200 mm diameter wafers or 300 mm diameter wafers, as well as rectangular or square panes. In some embodiments, the substrate comprises a rigid discrete material.

The substrate may have one or more features formed therein, one or more layers formed thereon, or combinations thereof. The shape of the feature can be any suitable shape including, but not limited to, trenches, holes and vias (circular or polygonal). As used in this regard, the term “feature” refers to any intentional surface irregularity. Suitable examples of features include but are not limited to trenches, which have a top, two sidewalls comprising, for example, a dielectric material, and a bottom extending into the substrate, the bottom comprising, for example, a metallic material, or vias which have one or more sidewalls extending into the substrate to a bottom.

The features described herein can extend vertically into the substrate and/or laterally within the substrate. Unless specifically indicated otherwise, the features described herein are not limited to either of a vertically extending feature or a laterally extending feature. In one or more embodiments, the substrate comprises at least one vertically extending feature. In one or more embodiments, the substrate comprises at least one laterally extending feature. In one or more embodiments, the substrate comprises at least one vertically extending feature and at least one laterally extending feature.

The features described herein can have any suitable aspect ratio (ratio of the depth of the feature to the width of the feature). In one or more embodiments, the aspect ratio of the features described herein is greater than or equal to about 1:1, 2:1, 5:1, 10:1, 15:1, 20:1, 25:1, 30:1, 35:1, 40:1, 50:1, 60:1, 70:1, 80:1, 90:1, 100:1, 125:1, or 150:1. In one or more embodiments, the aspect ratio of the features described herein is in a range of from 1:1 to 150:1.

The terms “on” or “thereon” each independently indicate that there is direct contact between elements. The terms “directly on” or “directly thereon” each independently indicate that there is direct contact between elements with no intervening elements.

As used in this specification and the appended claims, the terms “reactive compound”, “reactant,” “reactive gas”, “reactive species”, “precursor”, “process gas” and the like are used interchangeably to mean a substance with a species capable of reacting with the substrate or material on the substrate in a surface reaction (e.g., chemisorption, oxidation, reduction, cycloaddition).

A “pulse” or “dose” as used herein refers to a quantity of a source gas that is intermittently or non-continuously introduced into the processing chamber. The quantity of a particular compound within each pulse may vary over time, depending on the duration of the pulse. A particular process gas may include a single compound or a mixture/combination of two or more compounds.

The durations for each pulse/dose are variable and may be adjusted to accommodate, for example, the volume capacity of the processing chamber as well as the capabilities of a vacuum system coupled thereto. Additionally, the dose time of a reactive gas may vary according to the flow rate of the reactive gas, the temperature of the process gas, the type of control valve, the type of processing chamber employed, as well as the ability of the components of the process gas to adsorb onto the substrate. Dose times may also vary based upon the type of layer being formed and the geometry of the device being formed. A dose time should be long enough to provide a volume of compound sufficient to adsorb/chemisorb onto substantially the entire surface of the substrate and form a layer thereon.

As used herein, the term “conformal” means that the layer adapts to the contours of a feature or a layer. Conformality of a layer is typically quantified by a ratio of the average thickness of a layer deposited on the sidewalls of a feature to the average thickness of the same deposited layer on the field, or upper surface, of the substrate. As used herein, a layer that is “conformally deposited” refers to a layer where the thickness is about the same throughout. A layer which is conformal varies in thickness by less than or equal to about 5%, 2%, 1% or 0.5%. In one or more embodiments, the deposited film has a conformality greater than 90%, or greater than 91%, or greater than 92%, or greater than 93%, or greater than 94%, or greater than 95%, or greater than 96%, or greater than 97%, or greater than 98%, or greater than 99%.

As used herein, the term “in situ” refers to processes that are all performed in the same processing chamber or within different processing chambers that are connected as part of an integrated processing system, such that each of the processes are performed without an intervening vacuum break. As used herein, the term “ex situ” refers to processes that are performed in at least two different processing chambers such that one or more of the processes are performed with an intervening vacuum break. In some embodiments, one or more of the processes are performed without breaking vacuum or without exposure to ambient air.

As used herein, the terms “precursor,” “reactant,” “reactive gas,” “reactive species,” and the like are used interchangeably to refer to any species that can react with the substrate surface.

One or more of the layers deposited on the substrate or substrate surface are continuous. As used herein, the term “continuous” refers to a layer that covers an entire exposed surface without gaps or bare spots that reveal material underlying the deposited layer. A continuous layer may have gaps or bare spots with a surface area less than about 15% or less than about 10% of the total surface area of the layer.

The skilled artisan will recognize that the use of molecular formulae herein, e.g., aluminum oxide (AlOx), and the like does not imply a specific stoichiometric relationship between the elements but merely the identity of the major components of a material. For example, AlOx refers to a film whose major composition comprises aluminum (Al) atoms and oxygen (O) atoms. In some embodiments, the major composition of the specified film (i.e., the sum of the atomic percent of the specified atoms) is greater than or equal to about 95%, 98%, 99% or 99.5% of the film, on an atomic basis. The skilled artisan will appreciate that there are multiple instances where molecular formulae are used herein, and unless specifically indicated otherwise by the context, the molecular formulae do not imply a specific stoichiometric relationship between the elements, but merely the identity of the major components of the material. In instances where a specific stoichiometric relationship is stated, e.g., aluminum oxide (Al₂O₃), the specific stoichiometric relationship does not necessarily exclude generic molecular formulae that identify major components of the material, e.g., aluminum oxide (AlOx), unless specifically indicated otherwise by the context.

Generally, front-end of line (FEOL) refers to the first portion of integrated circuit fabrication, including transistor fabrication, middle-of-line (MOL) connects the transistor and interconnect parts of a chip using a series of contact structures, and back-end of line (BEOL) refers to a series of process steps after transistor fabrication through completion of a wafer.

Transistors are circuit components or elements that are often formed on semiconductor devices. Depending upon the circuit design, in addition to capacitors, inductors, resistors, diodes, conductive lines, or other elements, transistors are formed on a semiconductor device.

Generally, a transistor includes a gate formed between source and drain regions. In one or more embodiments, the source and drain regions include a doped region of a substrate, such as a semiconductor substrate, and exhibit a doping profile suitable for a particular application. The gate is positioned over the channel region and includes a gate dielectric interposed between a gate electrode and the channel region in the semiconductor substrate as used herein, the term “field effect transistor” or “FET” refers to a transistor that uses an electric field to control the electrical behavior of the device.

Field effect transistors are voltage controlled devices where their current carrying ability is changed by applying an electric field. Field effect transistors generally display very high input impedance at low temperatures. The conductivity between the drain and source terminals is controlled by an electric field in the device, which is generated by a voltage difference between the body and the gate of the device. The FET's three terminals are source(S), through which the carriers enter the channel; drain (D), through which the carriers leave the channel; and gate (G), the terminal that modulates the channel conductivity. Conventionally, current entering the channel at the source(S) is designated I_{S} and current entering the channel at the drain (D) is designated ID. Drain-to-source voltage is designated VDs. By applying voltage to gate (G), the current entering the channel at the drain (i.e. ID) can be controlled.

The metal-oxide semiconductor field-effect transistor (MOSFET) is a type of field-effect transistor (FET) and is used in integrated circuits and high speed switching applications. MOSFET has an insulated gate, whose voltage determines the conductivity of the device. This ability to change conductivity with the amount of applied voltage is used for amplifying or switching electronic signals. A MOSFET is based on the modulation of charge concentration by a metal-oxide-semiconductor (MOS) capacitance between a body electrode and a gate electrode located above the body and insulated from all other device regions by a gate dielectric layer. Compared to the MOS capacitor, the MOSFET includes two additional terminals (source and drain), each connected to individual highly doped regions that are separated by the body region. These regions can be either p or n type, but they are both of the same type, and of opposite type to the body region. The source and drain (unlike the body) are highly doped as signified by a “+” sign after the type of doping.

Generally, a metal-oxide-semiconductor (MOS) is a structure obtained by growing a high-κ dielectric layer on a layer of silicon oxide (SiOx) on top of a silicon substrate, followed by depositing a layer of metal or polycrystalline silicon on the high-κ dielectric layer. A CMOS device is a MOS device consisting of paired p-channel and n-channel transistors.

If the MOSFET is an n-channel or NMOS FET (′NMOS″ or “NFET”), then the source and drain are n+ regions and the body is a p region. If the MOSFET is a p-channel or PMOS FET (“PMOS” or “PFET”), then the source and drain are p+ regions and the body is an n region. The source is so named because it is the source of the charge carriers (electrons for n-channel, holes for p-channel) that flow through the channel; similarly, the drain is where the charge carriers leave the channel.

An “NMOS” or “NFET” is a MOS transistor where the active carriers are electrons flowing between n-type source and drain regions in an electrostatically formed n-channel in a p-type silicon substrate. A “PMOS” or “PFET” is a P-channel MOS transistor where the active carriers are holes flowing between p-type source and drain regions in an electrostatically formed p-channel in an n-type silicon substrate.

In one or more embodiments, a PMOS or PFET device comprises a silicon germanium (SiGe) channel to enhance hole mobility, for example, while an NMOS or NFET device comprises a silicon (Si) channel. These channels are typically positioned between a source region and a drain region.

In one or more embodiments, a PMOS or PFET device comprises a silicon germanium (SiGe) channel between a source region and a drain region and the NMOS or NFET device comprises a silicon (Si) channel between a source region and a drain region, or vice versa.

Shrinking of the materials currently used as NMOS and PMOS have become a challenge due to changes in basic properties, such as threshold voltage (Vₜ). The Vₜ tuning range will be limited by the film thickness variation with further scaling down of device sizes.

As used herein, the term “fin field-effect transistor (FinFET)” refers to a MOSFET transistor built on a substrate where the gate is placed on two, three, or four sides of the channel or wrapped around the channel, forming a double gate structure. FinFET devices have been given the generic name FinFETs because the source/drain region forms “fins” on the substrate. FinFET devices have fast switching times and high current density.

As used herein, the term “gate-all-around (GAA),” is used to refer to an electronic device, e.g., a transistor, in which the gate material surrounds the channel region on all sides. The channel region of a GAA transistor may include nanowires, nanosheets, nanoslabs, bar-shaped channels, or other suitable channel configurations known to one of skill in the art. In one or more embodiments, the channel region of a GAA device has multiple horizontal nanowires or horizontal bars vertically spaced, making the GAA transistor a stacked horizontal gate-all-around (hGAA) transistor.

As used herein, the term “nanowire” refers to a nanostructure, with a diameter on the order of a nanometer (10⁻⁹ meters). Nanowires can also be defined as the ratio of the length to width being greater than 1000. Alternatively, nanowires can be defined as structures having a thickness or diameter constrained to tens of nanometers or less and an unconstrained length. Nanowires are used in transistors and some laser applications, and, in one or more embodiments, are made of semiconducting materials, metallic materials, insulating materials, superconducting materials, or molecular materials. In one or more embodiments, nanowires are used in transistors for logic CPU, GPU, MPU, and volatile (e.g., DRAM) and non-volatile (e.g., NAND) devices. As used herein, the term “nanosheet” refers to a two-dimensional nanostructure with a thickness in a scale ranging from about 0.1 nm to about 1000 nm, or from 0.5 nm to 500 nm, or from 0.5 nm to 100 nm, or from 1 nm to 500 nm, or from 1 nm to 100 nm, or from 1 nm to 50 nm.

As used herein, “threshold voltage (Vₜ)” refers to the minimum gate-to-source voltage to create a conducting channel between the source and drain terminals, effectively turning a transistor “on.” “Multiple threshold voltage(s)” or “multi-Vₜ” technology includes transistors with varying threshold voltage(s) (Vₜ) to optimize circuit performance and power consumption.

In the following description, numerous specific details, such as specific materials, chemistries, dimensions of the elements, etc., are set forth to provide thorough understanding of one or more of the embodiments of the present disclosure. It will be apparent, however, to one of ordinary skill in the art that the one or more embodiments of the present disclosure may be practiced without these specific details. In other instances, semiconductor fabrication processes, techniques, materials, equipment, etc., have not been described in detail to avoid unnecessarily obscuring of this description. Those of ordinary skill in the art, with the included description, will be able to implement appropriate functionality without undue experimentation.

Embodiments of the present disclosure provided herein include processes for forming structures in field-effect-transistor (FET) devices and tuning a threshold voltage (Vₜ) of the structures for various uses. Threshold voltage (Vₜ) tuning is achieved by depositing a dipole dopant containing layer over a gate dielectric layer and driving the dipole dopants into the underlying gate dielectric layer by annealing. The process further includes providing protective layers, hardmasks, and compatible etch chemistries to protect regions of the FET device in which the threshold voltage (Vₜ) is not being modified. The process used herein is suitable for structures having thin individual layers, such as layers of about 20 Å or less, such as about 1 Å to about 10 Å.

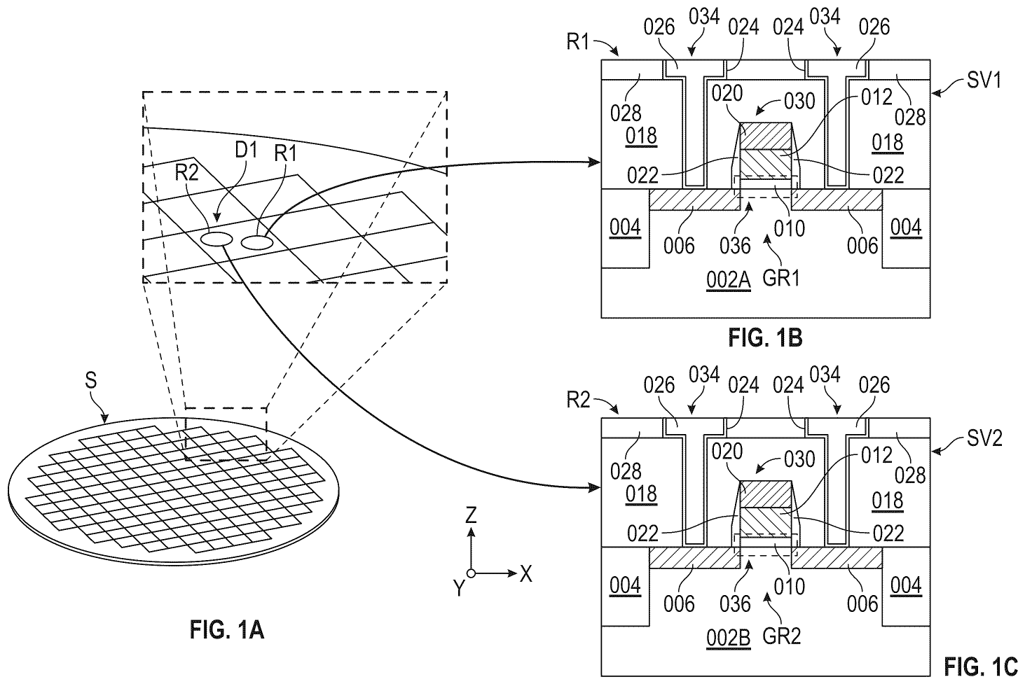

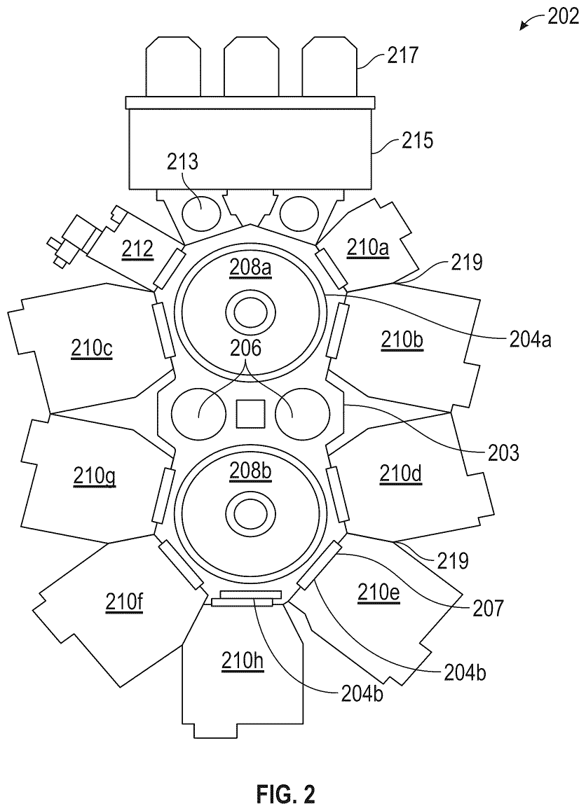

FIGS. 1A, 1B, and 1C depict a perspective view of a substrate S and cross-sectional views of transistors disposed on the substrate S, according to some embodiments. The substrate S includes a die D1. The die D1 includes a first region R1 and a second region R2. A first sectional view SV1 of the first region R1 is shown in FIG. 1B, and a second sectional view SV2 of the second region R2 is shown in FIG. 1C. In some embodiments, the first region R1 is a p-type metal-oxide-semiconductor field-effect transistor (PMOS) device having a gate region GR1, and the second region R2 is an n-type metal-oxide-semiconductor field-effect transistor (NMOS) device having a gate region GR2. The first region R1 can include a transistor including a p-type well region 002A with an active region defined by isolation regions 004. The second region R2 is a transistor including an n-type well region 002B with an active region defined by isolation regions 004. Each of the first region R1 and the second region R2 may also include source/drain regions disposed within the active region. The source/drain regions may include doped n-type regions (e.g., n-type regions), including lateral portions 006 and a first inter-layer dielectric (ILD) layer 018. As shown, the lateral portions 006 of the source/drain regions may be laterally adjacent to a semiconductor channel 036 in the well regions 002A, 002B. The first ILD layer 018 may be any suitable dielectric material, such as silicon oxide (SiO₂), borophosphosilicate glass (BPSG), phosphosilicate glass (PSG), or the like. The first ILD layer 018 may be deposited by chemical vapor deposition (CVD), furnace chemical vapor deposition (FCVD), or another appropriate deposition process.

The first region R1 includes a gate structure 030, which may include the gate region GR1. Similarly, the second region R2 includes a gate structure 030, which may include the gate region GR2. Each of the gate structures 030 may include a gate oxide layer 010, a first gate metal layer 012, and optionally a second gate metal layer 020. In some embodiments, the gate structure 030 includes spacers 022.

The first region R1 and the second region R2 may include metal interconnect structures 034. A second ILD layer 028, which may be a similar material as the first ILD layer 018, may be deposited in the same or a similar manner over the first ILD layer 018. The layers used to form the metal interconnect structures 034 may be deposited in the recesses formed in the first ILD layer 018 and second ILD layer 028, such as by use of CVD, ALD, or physical vapor deposition (PVD). The metal interconnect structures 034 can include a conformal barrier layer 024, such as titanium nitride (TiN), tantalum nitride (TaN), or the like, and metal fill 026 on the barrier layer 024, such as tungsten (W), aluminum (Al), copper (Cu), or the like.

While FIGS. 1A, 1B, and 1C illustrate a configuration that includes commonly configured metal-oxide-semiconductor field-effect transistor (MOSFET) devices being formed within the substrate S, this configuration is not intending to be limiting as to the scope of the disclosure provided herein, since other types of formed device structures may benefit from one or more aspects of the disclosure provided herein. The more conventional types of devices structures illustrated herein are only presented to simplify the discussion of the processes performed herein. However, it is believed that the processes described herein will provide a significant advantage for configurations where the device that is to be formed is more structurally complex, such as multi-gate devices, which may include gate-all-around (GAA) FET devices and/or FinFET types of devices, and where conventional processing techniques (e.g., implantation) of various gate dielectric materials are not accessible due to the gate regions of these multi-gate devices being buried within many different layers of the device.

FIG. 2 illustrates a processing system 202 that can be used to perform one or more of the processes described herein. The processing system 202 disclosed herein may include an Endura® II mainframe or an Endura® III mainframe available from Applied Materials, Inc. of Santa Clara, California. The processing system 202 includes a first transfer module 204a, a second transfer module 204b, and pass-through modules 206 connecting a first transfer chamber 208a of the first transfer module 204a to a second transfer chamber 208b of the second transfer module 204b. The first transfer module 204a includes a first process chamber 210a, a second process chamber 210b, a third process chamber 210c, an ancillary process chamber 212, and load lock chambers 213. The second transfer module 204b includes a fourth process chamber 210d, a fifth process chamber 210e, a sixth process chamber 210f, a seventh process chamber 210g, and an eighth process chamber 210h.

Each of the first transfer module 204a and the second transfer module 204b include a substrate handling robot (not shown) in the first transfer chamber 208a and the second transfer chamber 208b. The substrate handling robot of the first transfer module 204a is operable to transfer substrates between the load lock chambers 213, the first transfer chamber 208a, the process chambers 210a-210c, the ancillary process chamber 212, and the pass-through modules 206. The substrate handling robot of the second transfer module 204b is operable to transfer substrates between the pass-through modules 206, the second transfer chamber 208b, the process chambers 210d-210h. The processing system 202 includes load lock chambers 213 that are coupled to a factory interface 215. The factory interfaces 215 separately provides substrates to the processing system 202 via one or more factory interface (FI) robots (not shown) and front opening unified pods (FOUPs) 217.

Valves 207 are disposed at the interfaces of the process chambers 210a, 210b, 210c, the ancillary process chamber 212, and the load lock chambers 213 with the first transfer chamber 208a of the first transfer module 204a. The valves 207 are also disposed at the interfaces of the process chambers 210d, 210e, 210f, 210g, 210h with the second transfer chamber 208b of the second transfer module 204b. In one embodiment, which can be combined with other embodiments described herein, the valves 207 are slit valves and/or gate valves. Thus, the process chambers 210a-210h can be separately isolated from the first transfer chamber 208a and the second transfer chamber 208b. Vacuum pumps 219, such as cryopumps, turbopumps, or the like, may be coupled to the first transfer chamber 208a and the second transfer chamber 208b. The vacuum pumps 219 are operable to maintain the vacuum levels of the first transfer chamber 208a and the second transfer chamber 208b. The vacuum level may increase or decrease in each of the first transfer chamber 208a and the second transfer chamber 208b as one or more substrates are transferred between the first transfer chamber 208a and the second transfer chamber 208b.

In this configuration, the transfer of the substrates within the processing system 202 can be completed while the substrates are disposed within a high vacuum environment (e.g., 10⁻⁷-10⁻⁹ Torr), since the vacuum level in the second transfer chamber 208b is maintained at a higher base pressure than the vacuum level maintained in the first transfer chamber 208a. Typically, the base pressure or vacuum level increases (i.e., lower pressure) as the substrate is moved through the first transfer module 204a to the second transfer module 204b within the processing system 202 in a direction from the load lock chambers 213 (e.g., 10⁻³ Torr) to the second transfer chamber 208b (e.g., 10⁻⁷-10⁻⁸ Torr) and the process chambers 210d-210g (e.g., 10⁻⁸-10⁻⁹ Torr).

The process chambers 210a-210h may be any type of process chambers such as deposition chambers, e.g., physical vapor deposition (PVD) chambers, chemical vapor deposition (CVD) chambers, plasma enhanced chemical vapor deposition (PECVD) chambers, atomic layer deposition (ALD) chambers, plasma enhanced atomic layer deposition (PEALD) chambers, etch chambers, degas chambers, and/or any other type of process chambers. The types of the process chambers 210a-210h are interchangeable in the processing system 202.

In one embodiment, the process chambers 210d, 210e, 210f, 210g, 210h are ALD chambers that are configured to deposit a dipole layer, such as a p-type dipole layer. In this configuration, the process chambers 210b and 210c can include rapid thermal processing (RTP) chambers that are configured to heat substrates to drive the dipole layer with high-k dielectric layer. One or more of the process chambers 210a and 212 may be preclean chambers, such as an Aktiv™ Preclean (“APC”) chamber available from Applied Materials, Inc. of Santa Clara, California. In another embodiment, one or more of the process chambers 210d, 210e, 210f, 210g, 210h are configured to deposit a diffusion barrier layer by an ALD process.

The processing system 202 includes a system controller 203 that receives data corresponding to the throughput of each of the process chambers 210a-210h. The system controller 203 is operable to apply predictive modeling to the data in order to provide instructions corresponding to process commands directed to processing in and transfer of one or more substrates from the process chambers 210a-210h of the processing systems 202. The system controller 203 may also provide an output corresponding to the optimal combination of PVD chambers, CVD chambers, PECVD chambers, ALD chambers, PEALD chambers, etch chambers, degas chambers, or any other type of process chambers for the process chambers 210a-210h of the processing system 202.

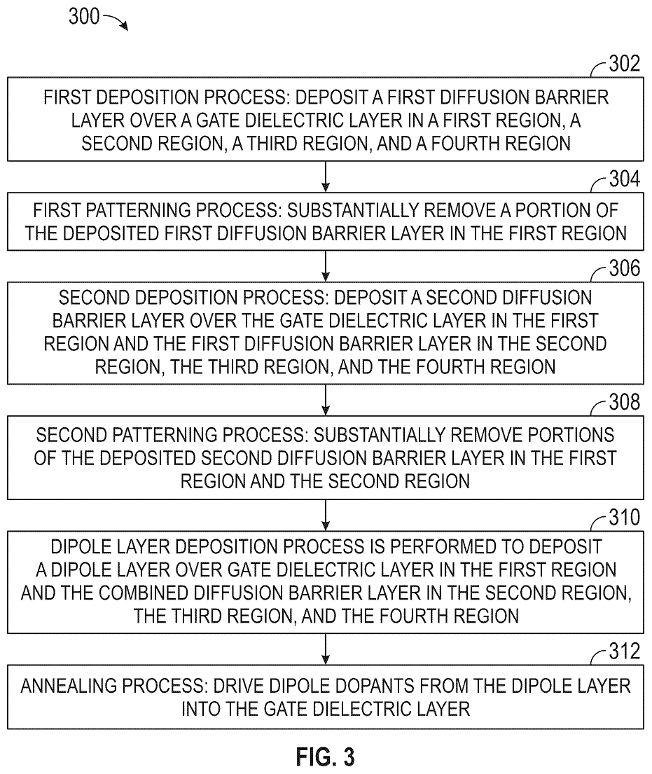

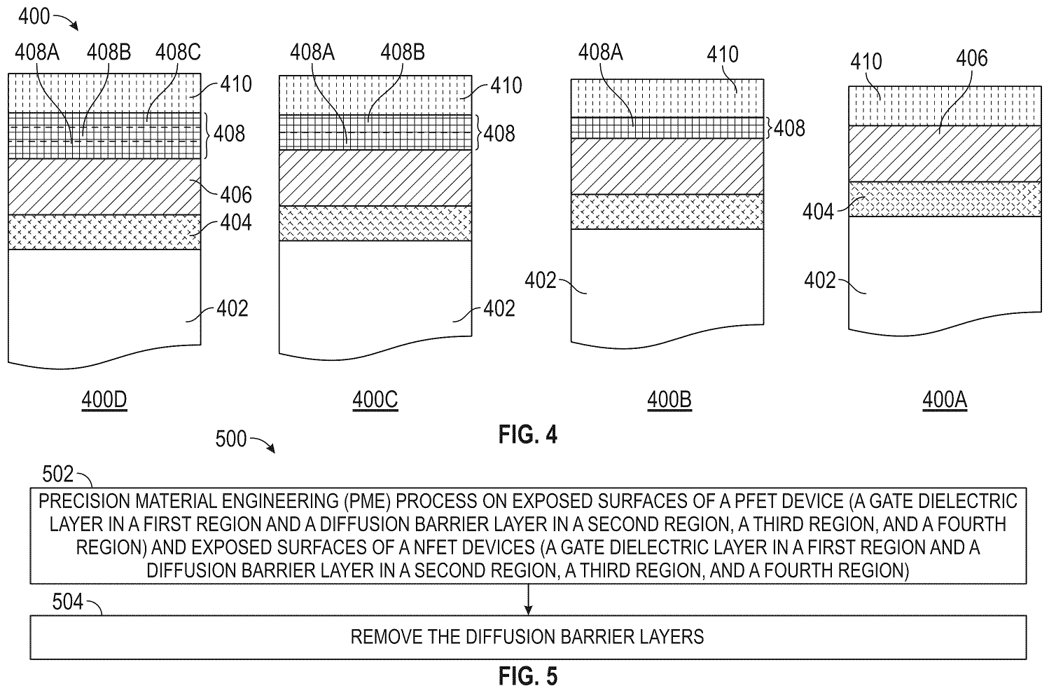

FIG. 3 depicts a process flow diagram of a method 300 of altering characteristics of a gate dielectric layer used in a field-effect-transistor (FET) device in a semiconductor structure 400 shown in FIG. 4, according to some embodiments. In some embodiments, each of the layers deposited during the activities performed in the method 300 are deposited using atomic layer deposition (ALD) processes.

As shown in FIG. 4, the semiconductor structure 400 may include a first region 400A, a second region 400B, a third region 400C, and a fourth region 400D. Each of the regions 400A, 400B, 400C, and 400D include a substrate 402, an interfacial layer 404 formed on the substrate 402, and a gate dielectric layer 406 formed on the interfacial layer 404. The substrate 402 may be a silicon containing substrate (e.g., n-type Si substrate, p-type Si substrate). The interfacial layer 404 may be formed of silicon oxide (SiO₂).

The gate dielectric layer 406 may be formed of a high-k dielectric material. As used herein, a high-k dielectric material is a material having a dielectric constant greater than a dielectric constant of silicon oxide (SiO₂) (e.g., about 3.9). In some embodiments, the gate dielectric layer 406 is formed of a metal oxide. In some embodiments, the high-k dielectric material is a hafnium-containing material, a silicon containing material, a zirconium-containing material, a titanium-containing material, or combinations thereof. In some embodiments, the high-k dielectric material is a hafnium oxide containing material (e.g., HfO₂) or other suitable materials. The gate dielectric layer 406 is deposited at a thickness of about 20 Å or less, such as about 5 Å to about 15 Å. The gate dielectric layer 406 interfaces the interfacial layer 404. In one example, the gate dielectric layer 406 is formed over a channel region of a metal gate field-effect-transistor (FET) device, and the gate dielectric layer 406 includes an interfacial layer formed of silicon oxide (SiO₂) and a dielectric layer of hafnium oxide (HfO₂) formed thereon.

The method 300 begins with activity 302, in which a first deposition process is performed to deposit a first diffusion barrier layer 408A over the gate dielectric layer 406 in the first region 400A, the second region 400B, the third region 400C, and the fourth region 400D. The deposited first diffusion barrier layer 408A has a first diffusion barrier layer thickness of about 0 Å to about 15 Å, such as about 1 Å to about 10 Å, such as about 3 Å to about 5 Å. The diffusion barrier layer 408A may be formed of a metal nitride material, such as a titanium nitride (TiN), tantalum nitride (TaN), tungsten nitride (W₂N, WN, WN₂), or combinations thereof.

In activity 304, a first patterning process is performed to substantially remove a portion of the deposited first diffusion barrier layer 408A in the first region 400A. The first patterning process includes many processing steps, such one or more deposition steps, one or more lithography steps, one or more developing steps, and one or more etching steps. After performing the first patterning process, the portion of the deposited first diffusion barrier layer 408A in the first region 400A is substantially removed. The second region 400B, the third region 400C, and the fourth region 400D each includes a portion of the deposited first diffusion barrier layer 408A.

In activity 306, a second deposition process is performed to deposit a second diffusion barrier layer 408B over exposed surfaces of the semiconductor structure 400 (the gate dielectric layer 406 in the first region 400A and the first diffusion barrier layer 408A in the second region 400B, the third region 400C, and the fourth region 400D). The deposited second diffusion barrier layer 408B has a second diffusion barrier layer thickness of about 0 Å to about 15 Å, such as about 1 Å to about 10 Å, such as about 3 Å to about 5 Å. In one example, the second diffusion barrier layer 408B is formed of the same material as the first diffusion barrier layer 408A. The second deposition process in activity 306 may be the same deposition process as the first deposition process in activity 302.

In activity 308, a second patterning process is performed to substantially remove portions of the deposited second diffusion barrier layer 408B in the first region 400A and the second region 400B. The second patterning process includes many processing steps, such as one or more deposition steps, one or more lithography steps, one or more developing steps, and one or more etching steps. After performing the second patterning process, the portions of the deposited second diffusion barrier layer 408B in the first region 400A and the second region 400B are substantially removed. The second region 400B includes a portion of the deposited first diffusion barrier layer 408A. The third region 400C and the fourth region 400D each include a portion of the first diffusion barrier layer 408A and a portion of the second diffusion barrier layer 408B.

Additional regions, such as the fourth region 400D, can further include a portion of an additional diffusion barrier layer, such as a third diffusion barrier layer 408C having a third diffusion barrier layer thickness of about 0 Å to about 15 Å, such as about 1 Å to about 10 Å, such as about 3 Å to about 5 Å, which can be formed by deposition and etch back (e.g., similar to activities 302 and 304) until the semiconductor structure 400 includes different regions with a diffusion barrier layer 408 having different diffusion barrier thicknesses. For example, a combined diffusion barrier layer 408 in the second region 400B is the first diffusion barrier layer 408A, and thus has a thickness equal to the first diffusion barrier layer thickness. The combined diffusion barrier layer 408 in the third region 400C is a combination of the first diffusion barrier layer 408A and the second diffusion barrier layer 408B, and thus has a thickness equal to a combined thickness of the first diffusion barrier layer thickness and the second diffusion barrier layer thickness. The combined diffusion barrier layer 408 in the fourth region 400D is a combination of the first diffusion barrier layer 408A, the second diffusion barrier layer 408B, and the third diffusion barrier layer 408C, and thus has a thickness equal to a combined thickness of the first diffusion barrier layer thickness, the second diffusion barrier layer thickness, and the third diffusion barrier layer thickness. In one example, the third diffusion barrier layer 408C is formed of the same material as the first diffusion barrier layer 408A and/or the second diffusion barrier layer 408B.

In some alternate embodiments, forming diffusion barrier layers 408 having varying thickness in different regions of the semiconductor structure 400 includes depositing a hardmask over the diffusion barrier layer 408, patterning the hardmask, and etching portions of the diffusion barrier layer 408 through openings of the patterned hardmask. For example, subsequent to the deposition of the hardmask over the diffusion barrier layer 408, an opening in the hardmask is formed in the first region 400A and then the diffusion barrier layer 408 in the first region 400A is etched. Subsequently, an opening in the hardmask is formed in the second region 400B and then the diffusion barrier layer 408 in the second region 400B is partially etched to a thickness of the first diffusion barrier layer 408A. Another opening in the hardmask is formed in the third region 400C and then the diffusion barrier layer 408 in the third region 400C is partially etched to a thickness of a combination of the first diffusion barrier layer 408A and the second diffusion barrier layer 408B. In some embodiments, the hardmask is formed of refractory metal nitride or carbide. The hardmask can be deposited over a protective layer disposed over the diffusion barrier layer 408. The hardmask is deposited to a thickness of about 10 Å to about 20 Å. Other processes and methods of depositing the diffusion barrier layer with varying thickness across various regions of the semiconductor structures 400 are also contemplated.

In activity 310, a dipole layer deposition process is performed to deposit a dipole layer 410 over gate dielectric layer 406 in the first region 400A and the combined diffusion barrier layer 408 in the second region 400B, the third region 400C, and the fourth region 400D. The dipole layer 410 includes dipole dopants. In general, dipole dopants include elements that form an electrostatic dipole, and are different from fixed charge types of dopants that include elements that form a positive or a negative charge due to the loss or gain of an electron when doped within a dielectric material. While not intending to be bound by theory, the presence of dipole dopants in a dielectric film is believed to lead to a surface potential at an interface of the gate dielectric layer 406, which leads to dielectric polarization in the dielectric film. The dielectric polarization caused by the presence of a desired amount of dipole dopants in a gate dielectric layer 406 can then be used to adjust a threshold voltage (Vₜ) of the FET device. A threshold voltage (Vₜ) is the minimum gate-to-source voltage that is needed to create a conducting path between the source and the drain terminals. In some embodiments, it is desirable to dope different regions of the gate dielectric layer (e.g., metal gate interface surface, interface surface between a high-k layer and an interfacial dielectric layer, or channel interface surface) to further adjust the threshold voltage (Vₜ) of a FET. The dipole dopants in the dipole layer 410 can be a metal dopant, such as aluminum (Al) or lanthanum (La). The dipole layer provides the dipole dopants that is to be diffused into the gate dielectric layer 406 by subsequent annealing.

The dipole layer 410 has a dipole layer thickness of about 3 Å to about 10 Å, such as about 5 Å to about 8 Å. In some embodiments, the dipole layer 410 is formed of a metal nitride, such as titanium nitride that further includes dipole dopants.

In some embodiments, the dipole layer 410 has a uniform concentration of dipole dopants of about 1% to about 20%, such as about 5% to about 15%, such as about 8% to about 12% throughout the thickness of the dipole layer 410. Selecting the dipole dopant concentration in the dipole layer 410 is based on a predetermined final concentration of dipole dopants to be diffused into the gate dielectric layer 406. The predetermined concentration of dipole dopants to be diffused into the gate dielectric layer 406 is determined based on a predetermined threshold voltage (Vₜ) of at least one of the regions (e.g., 400A, 400B, 400C, 400D) or a predetermined difference in threshold voltage (Vₜ) of a FET device formed in one of the regions (e.g., 400A, 400B, 400C, 400D) relative to a FET device formed in another of the regions (e.g., 400A, 400B, 400C, 400D). In some embodiments, the dipole layer 410 has a substantially uniform concentration of dipole dopants within the dipole layer.

In some other embodiments, the dipole layer 410 has a gradient concentration of dipole dopants that varies along the thickness of the dipole layer 410, for example, a higher concentration at a surface of the dipole layer 410 closer to the gate dielectric layer 406 and a lower concentration at the opposite surface of the dipole layer 410. In some embodiments, the dipole dopants is formed by an atomic layer deposition (ALD) process. In some embodiments, a gradient concentration of the dipole dopants within the dipole layer 410 is formed by delivering ALD pulses that contain a dipole-dopant containing precursor with a concentration that is increasing every successive layer (i.e., positive gradient) or decreasing every successive layer (i.e., negative gradient) during the ALD process. In one example, about 70 at. % or more, such as about 80% or more, such as about 90% or more of the dipole dopants is disposed in a portion of the dipole layer 410 that is formed the surface of the dipole layer 410 closer to the gate dielectric layer 406, and such as a lower 50%, such as a lower 20% in the rest of the dipole layer 410 (i.e., negative gradient). In some embodiments, forming the gradient concentration of the dipole dopants includes increasing a time of exposure (e.g., pulse time) of the dipole dopants relative to a time of exposure of the other gases during the ALD process.

Without being bound by theory, it is believed that varying a thickness of the diffusion barrier layer 408 can control a dipole density at various regions of the semiconductor structure 400. In some embodiments, a diffusion barrier layer (not shown in FIG. 4) in the first region 400A is less than about 0.3 nm, such as 0 nm (thinnest), and the threshold voltage (Vₜ) shift is “ultra low.” The diffusion barrier layer 408 of the second region 400B is about 0.3 nm to about 0.6 nm and the threshold voltage (Vₜ) is “low” and greater than the threshold voltage (Vₜ) of the first region 400A. The diffusion barrier layer 408 of the third region 400C is about 0.6 nm to about 1 nm and the threshold voltage (Vₜ) is “standard” and greater than the threshold voltage (Vₜ) of the second region 400B. The diffusion barrier layer 408 of the fourth region 400D is about 1 nm or greater (thickest) and the threshold voltage (Vₜ) is “high” and greater than the threshold voltage (Vₜ) of the third region 400C.

In activity 312, an annealing process is performed to drive dipole dopants from the dipole layer 410 into the gate dielectric layer 406. In some embodiments, the annealing process is performed at a temperature of about 600° C. to about 1100° C., such as about 800° C. to about 1000° C., or about 700° C. to about 950° C. In some embodiments, the annealing process is performed for a duration of about 0.5 seconds to about 15 seconds, such as about 1 second to about 10 seconds. Annealing the semiconductor structure 400 enables the dipole dopants from the dipole layer 410 to diffuse into the gate dielectric layer 406. Without being bound by theory, in one configuration, the dipole dopant diffused into the gate dielectric layer 406 produces a threshold voltage (Vₜ) shift in the gate dielectric layer 406 at an interface with the underlying interfacial layer 404 (e.g., silicon dioxide (SiO₂)) formed on the substrate 402. It has been discovered that selection of the dopant type and concentration enables modulation of the threshold voltage (Vₜ) either positively or negatively as compared to the threshold voltage (Vₜ) of an un-doped dielectric layer, depending on desired application. In some embodiments, the dipole dopant is a p-type dopant that is diffused into the gate dielectric layer 406 to induce negative polarization and lower threshold voltage (Vₜ). In some embodiments, other dopants are contemplated to raise the threshold voltage (Vₜ). It is further believed that the dipole dopant is diffused from the dipole layer 410 to the lower portion of the gate dielectric layer 406 (e.g., interface of the gate dielectric layer and the interfacial layer 404) and disturbs an oxygen density in the lower portion of the gate dielectric layer 406 (e.g., HfO₂) relative to the underlying interfacial layer 404 (e.g., silicon dioxide (SiO₂)).

After performing the activities of the method 300, additional steps may be performed to form FET devices that have differing and desirable threshold voltage (Vₜ) characteristics. In some embodiments, a first FET is formed that has a first threshold voltage (Vₜ) value. The first FET includes at least a portion of the dielectric layer found in the first region (e.g., the gate region GR1) after the semiconductor structure 400 was exposed to the annealing process. In some embodiments, a second FET is formed that has a second threshold voltage (Vₜ) value. The second FET includes at least a portion of the dielectric layer found in the second region (e.g., the gate region GR2) after the semiconductor structure 400 was exposed to the annealing process. The first threshold voltage (Vₜ) value is different from the second threshold voltage (Vₜ) value. Therefore, by adjusting the amount of the dipole dopant that is driven into the gate dielectric layer 406 during activity 312, due to the presence of the varying thicknesses of the diffusion barrier layer 408, the threshold voltage (Vₜ) value can be adjusted. In cases where the first, second, third and fourth regions form parts of a PMOS device the first region 400A typically has an ultra low threshold voltage (Vₜ), the second region 400B has a low threshold voltage (Vₜ), the third region 400C has a standard threshold voltage (Vₜ), and the fourth region 400D has a high threshold voltage (Vₜ).

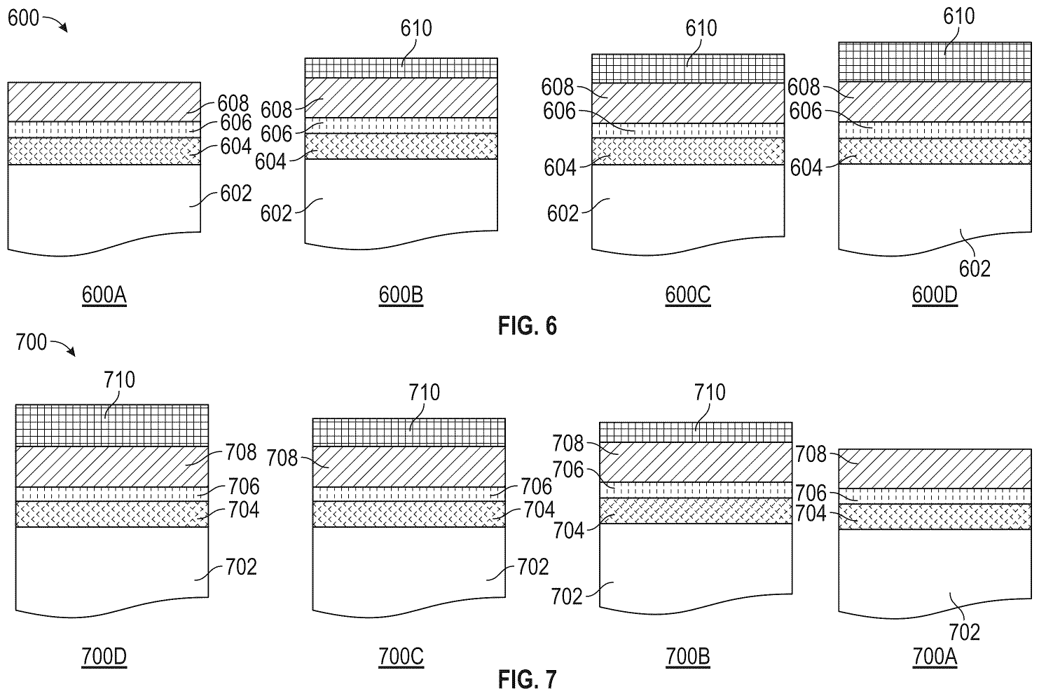

FIG. 5 depicts a process flow diagram of a method 500 of altering the characteristics of a gate dielectric layer used in a PFET device 600 shown in FIG. 6 and a NFET device 700 shown in FIG. 7, according to some embodiments. The method 500 can be used for altering of the threshold voltage (Vₜ) in devices that include a dipole layer between an interfacial layer and a dielectric layer, without forming an additional dipole layer.

As shown in FIG. 6, the PFET device 600 includes a substrate 602, an interfacial layer 604 on the substrate 602, a p-type dipole layer 606 on the interfacial layer 604, and a gate dielectric layer 608 on the p-type dipole layer 606. As shown in FIG. 7, the NFET device 700 includes a substrate 702, an interfacial layer 704 on the substrate 702, an n-type dipole layer 706 on the interfacial layer 704, and a gate dielectric layer 708 on the n-type dipole layer 706. The interfacial layer 604 and the interfacial layer 704 may be formed of silicon oxide (SiO₂). The p-type dipole layer 606 may include p-type dipole dopants and have a thickness of about 3 Å to about 10 Å, such as about 5 Å to about 8 Å. The n-type dipole layer 706 may include n-type dipole dopants and have a thickness of about 3 Å to about 10 Å, such as about 5 Å to about 8 Å. The gate dielectric layer 608 and the gate dielectric layer 708 may be formed a high-k dielectric material and have a thickness of about 5 Å to about 15 Å.

A first region 600A of the PFET device 600 and a first region 700A of the NFET device 700 do not include diffusion barrier layers. A second region 600B of the PFET device 600 and a second region 700B of the NFET device 700 each include a diffusion barrier layer 610 and a diffusion barrier layer 710. A third region 600C of the PFET device 600 and a third region 700C of the NFET device 700 each include a thicker diffusion barrier layer 610 relative to the second region 600B and a thicker diffusion barrier layer 710 relative to the second region 700B. A fourth region 600D of the PFET device 600 and a fourth region 700D of the NFET device 700 each include a thicker diffusion barrier layer 610 relative to the third region 600C and a thicker diffusion barrier layer 710 relative to the third region 700C. The diffusion barrier layers 610 and 710 having varying thickness can be formed by a similar process to the method 300 as described above in relation to FIGS. 3 and 4.

The method 500 begins with activity 502, in which a precision material engineering (PME) process is performed on exposed surfaces of the PFET device 600 (the gate dielectric layer 608 in the first region 600A and the diffusion barrier layer 610 in the second region 600B, the third region 600C, and the fourth region 600D) and exposed surfaces of the NFET devices 700 (the gate dielectric layer 708 in the first region 700A and the diffusion barrier layer 710 in the second region 700B, the third region 700C, and the fourth region 700D). The PME process includes exposing the exposed surfaces of the PFET device 600 and the exposed surface of the NFET device 700 to a nitrogen containing species, such as a nitrogen radical. In some embodiments, the PME process is performed by use of a decoupled plasma nitridation (DPN) process that is available from Applied Materials.

In activity 504, after the PME process, the diffusion barrier layers 610 and 710 are removed.

Without being bound by theory, for PFET devices having a p-type dipole layer, such as the p-type dipole layer 606, the greater the thickness of the diffusion barrier layer 610, the lower the threshold voltage (Vₜ) of the region. In particular, the threshold voltage (Vₜ) of the first region 600A is higher than the second region 600B, which is higher than the third region 600C, which is higher than the fourth region 600D.

Without being bound by theory, for NFET devices having an n-type dipole layer, such as the n-type dipole layer 706, the greater the thickness of the diffusion barrier layer 710, the higher the threshold voltage (Vₜ) of the region. In particular, the threshold voltage (Vₜ) of the first region 600A is lower than the second region 600B, which is lower than the third region 600C, which is lower than the fourth region 600D.

In some embodiments, the PME process of the method 500 can be used for altering the characteristics of a gate dielectric layer in a PFET device 800 that is free of the dipole layer.

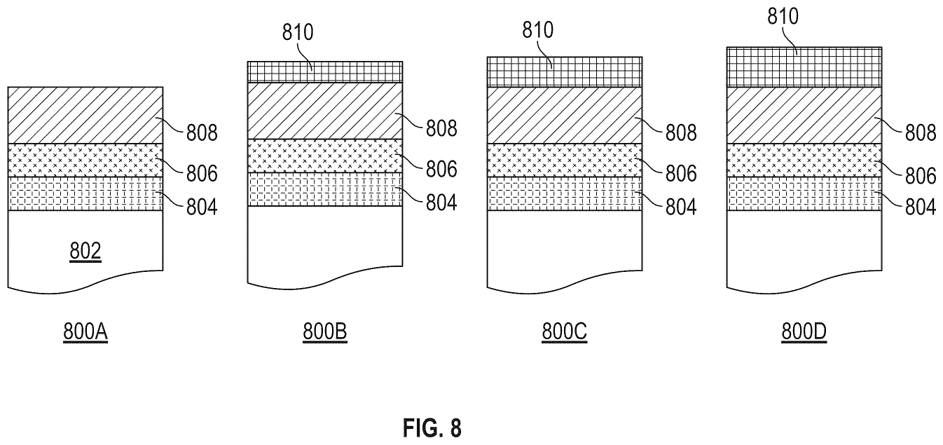

As shown in FIG. 8, the PFET device 800 includes a substrate 802, a silicon-germanium containing layer 804 on the substrate 802, an interfacial layer 806 on the silicon-germanium containing layer 804, a gate dielectric layer 808 on the interfacial layer 806, and a diffusion barrier layer 810 on the gate dielectric layer 808. A first region 800A of the PFET device 800 does not include a diffusion barrier layer. A second region 800B of the PFET device 800 includes a diffusion barrier layer 810. A third region 800C of the PFET device 800 has a thicker diffusion barrier layer 810 relative to the second region 800B. A fourth region 800D of the PFET device 800 has the thickest diffusion barrier layer 810. The interfacial layer 806 has a thickness of about 3 Å to about 8 Å. The silicon-germanium containing layer 804 has a thickness of about 15 Å to about 25 Å. After performing a PME process (e.g., nitridation process) on exposed surfaces (the gate dielectric layer 808 in the first region 800A and the diffusion barrier layer 810 in the second region 800B, the third region 800C, and the fourth region 800D) of the PFET device 800, the threshold voltage (Vₜ) values decrease from the first region 800A to the fourth region 800D.

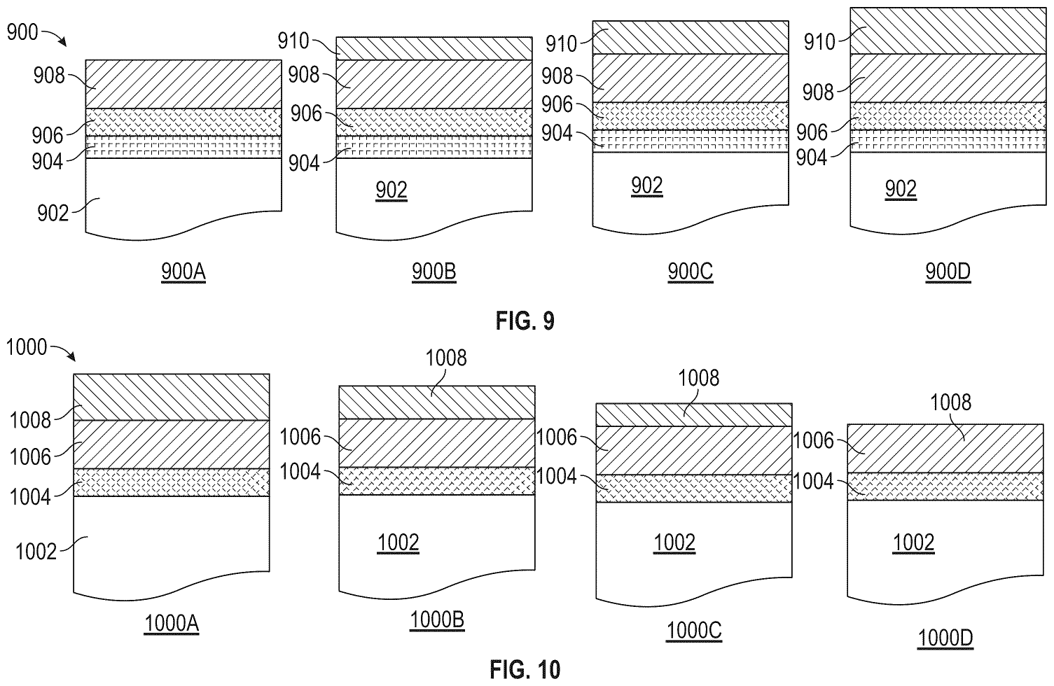

In some embodiments, forming an n-type dipole layer having varying thickness as in the method 300 can be used for altering the characteristics of a gate dielectric layer used in a PFET device 900 shown in FIG. 9 and an NFET device 1000 shown in FIG. 10. The PFET device 900 includes a substrate 902, a silicon-germanium containing layer 904, an interfacial layer 906, a gate dielectric layer 908, and an n-type dipole layer 910. The NFET device 1000 includes a substrate 1002, an interfacial layer 1004, a gate dielectric layer 1006, and an n-type dipole layer 1008. The n-type dipole layer 910 and the n-type dipole layer 1008 may be formed of lanthanum oxide. For PFET device 900, the thicker the formed n-type dipole layer 910, the higher the threshold voltage (Vₜ) that will be realized by the different regions after an annealing process (e.g., RTP process) is performed to drive the dipole dopants from the n-type dipole layer 910 into the gate dielectric layer 908 and from the n-type dipole layer 1008 into the gate dielectric layer 1006. For the NFET device 1000, the thicker the n-type dipole layer 1008, the lower the threshold voltage (Vₜ) that will be realized by the different regions after the drive-in process is performed. The different thickness formed on each of the regions (both PMOS and NMOS) can be formed together during the process of forming each thickness on of the n-type dipole layer 910 on the substrate.

Some embodiments employ diffusion barrier layers configured to provide multiple threshold voltages (multi-Vₜ) through controlled dopant diffusion. It has been advantageously found that varying the thickness of the diffusion barrier layers is configured to allow selective modulation of dipole penetration into the high-k dielectric layer and interfacial layer, enabling precise threshold voltage (Vₜ) tuning across device regions. Some embodiments provide integration schemes that are configured to enable controllable dipole diffusion through the use of diffusion barrier layers and capping layers, allowing for multi-Vₜ tuning. The integration schemes described herein are advantageously configured to control dipole drive-in using varying diffusion barrier layer thickness—without altering the dipole deposition thickness—offering improved threshold voltage (Vₜ) control and process flexibility. The integration schemes described herein advantageously meet thickness requirements as devices continue to scale down.

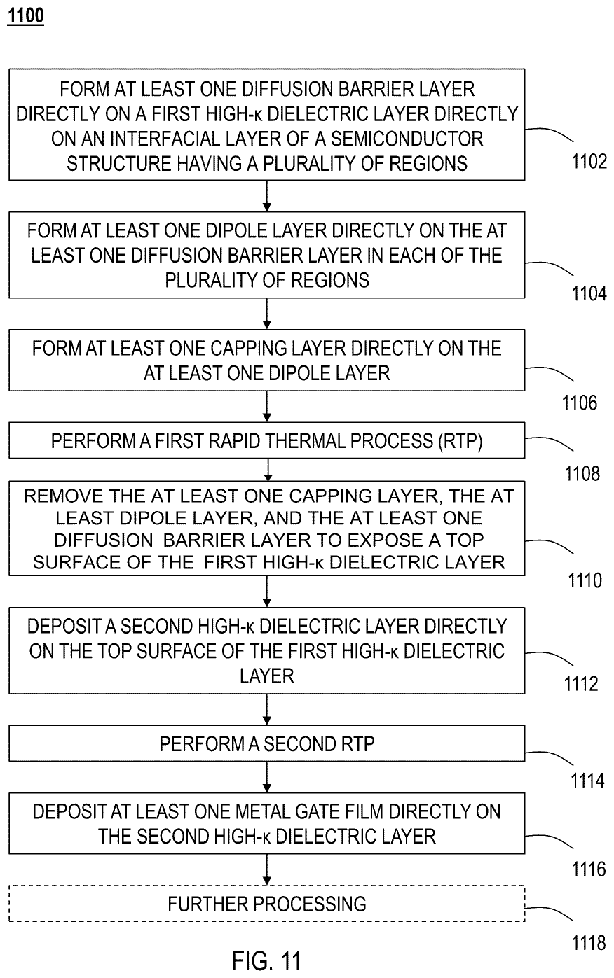

FIG. 11 depicts a process flow diagram of a method 1100 for processing a substrate, according to some embodiments. In some embodiments, the method 1100 comprises, consists essentially of, or consists of forming at least one diffusion barrier layer directly on a first high-κ dielectric layer directly on an interfacial layer of a semiconductor structure having a plurality of regions (activity 1102); forming at least one dipole layer directly on the at least one diffusion barrier layer in each of the plurality of regions (activity 1104); forming at least one capping layer directly on the at least one dipole layer (activity 1106); performing a first rapid thermal process (RTP) to drive atoms from the at least one dipole layer into an interface between the first high-κ dielectric layer and the interfacial layer in each of the plurality of regions (activity 1108); removing the at least one capping layer, the at least one dipole layer, and the at least one diffusion barrier layer in each of the plurality of regions to expose a top surface of the first high-κ dielectric layer (activity 1110); depositing a second high-κ dielectric layer directly on the top surface of the first high-κ dielectric layer in each of the plurality of regions (activity 1112); performing a second RTP in each of the plurality of regions (activity 1114); and depositing at least one metal gate film directly on the second high-κ dielectric layer in each of the plurality of regions to form multiple threshold voltages (multi-Vₜ) including a different threshold voltage (Vₜ) in each of the plurality of regions of the semiconductor structure (activity 1116); and optionally, one or more processing operations (activity 1118).

In some embodiments, the method 1100 includes a first cycle, a second cycle, and a third cycle, the first cycle comprising, consisting essentially of, or consisting of forming a first diffusion barrier layer directly on a first high-κ dielectric layer directly on an interfacial layer of a semiconductor structure having a first region, a second region, and a third region, the first diffusion barrier layer formed on the first region (activity 1102); forming a first dipole layer directly on the first diffusion barrier layer (activity 1104); forming a first capping layer directly on the first dipole layer (activity 1106); performing a first rapid thermal process (RTP) to drive atoms from the first dipole layer into an interface between the first high-κ dielectric layer and the interfacial layer in the first region (activity 1108); removing the first capping layer, the first dipole layer, and the first diffusion barrier layer in the first region to expose a top surface of the first high-κ dielectric layer (activity 1110); depositing a second high-κ dielectric layer directly on the top surface of the first high-κ dielectric layer in the first region (activity 1112); performing a second RTP (activity 1114); and depositing at least one metal gate film directly on the second high-κ dielectric layer to form a first threshold voltage (Vₜ) in the first region (activity); and optionally, one or more processing operations (activity 1118).

In some embodiments, the second cycle is performed after the first cycle, the second cycle comprising, consisting essentially of, or consisting of forming a second diffusion barrier directly on the first high-κ dielectric layer in the second region (activity 1102); forming a second dipole layer directly on the second diffusion barrier layer (activity 1104); forming a second capping layer directly on the second dipole layer (activity 1106); performing a first rapid thermal process (RTP) to drive atoms from the second dipole layer into an interface between the first high-κ dielectric layer and the interfacial layer in the second region (activity 1108); removing the second capping layer, the second dipole layer, and the second diffusion barrier layer in the second region to expose a top surface of the first high-κ dielectric layer (activity 1110); depositing a second high-κ dielectric layer directly on the top surface of the first high-κ dielectric layer in the second region (activity 1112); performing a second RTP (activity 1114); and depositing at least one metal gate film directly on the second high-κ dielectric layer to form a second threshold voltage (Vₜ) in the second region (activity 1116); and optionally, one or more processing operations (activity 1118).

In some embodiments, the third cycle is performed after the second cycle, the third cycle comprising, consisting essentially of, or consisting of forming a third diffusion barrier directly on the first high-κ dielectric layer in the third region (activity 1102); forming a third dipole layer directly on the third diffusion barrier layer (activity 1104); forming a third capping layer directly on the third dipole layer (activity 1106); performing a first rapid thermal process (RTP) to drive atoms from the third dipole layer into an interface between the first high-κ dielectric layer and the interfacial layer in the third region (activity 1108); removing the third capping layer, the third dipole layer, and the third diffusion barrier layer in the third region to expose a top surface of the first high-κ dielectric layer (activity 1110); depositing a second high-κ dielectric layer directly on the top surface of the first high-κ dielectric layer in the third region (activity 1112); performing a second RTP (activity 1114); and depositing at least one metal gate film directly on the second high-κ dielectric layer to form a third threshold voltage (Vₜ) in the third region (activity 1116); and optionally, one or more processing operations (activity 1118).

In some embodiments, activity 1102 includes forming at least one diffusion barrier layer directly on a first high-κ dielectric layer directly on an interfacial layer of a semiconductor structure having a plurality of regions.

The interfacial layer may be deposited on the substrate by a deposition technique, such as, but not limited to, ALD, CVD, PVD, MBE, MOCVD, spin-on, radical-assisted doping, or other deposition techniques.

The interfacial layer can have any suitable thickness. In one or more embodiments, the interfacial layer has a thickness in a range of from about 3 Å to about 10 Å.

In some embodiments, the interfacial layer comprises silicon oxide (SiOx). In one or more embodiments, the interfacial layer comprises a silicon oxide (SiOx) layer formed on doped silicon or undoped silicon. In one or more embodiments, the interfacial layer may be formed by etching and an oxide forming on substrate.

In some embodiments, a wet chemistry technique is performed to form the interfacial layer. The wet chemistry technique may be any suitable technique. In some embodiments, the wet chemistry technique includes a pre-clean process. In some embodiments, the pre-clean process includes using a SC-1 solution comprising one or more of ozone, ammonium hydroxide, or hydrogen peroxide. In some embodiments, the pre-clean process includes using a SC-1 solution without ozone, ammonium hydroxide, or hydrogen peroxide. In some embodiments, after using the SC-1 solution, the pre-clean process includes using dilute hydrofluoric acid (dilute HF), including greater than 100:1, such as 130:1 dilute HF, to etch away native oxide on the substrate to form a hydrophobic surface (i.e., the interfacial layer).

In some embodiments, a rapid thermal process (RTP) is used to form the interfacial layer. The RTP may be any suitable process. In some embodiments, the RTP is a thermal oxidation process to form the interfacial layer comprising silicon oxide (SiOx).

The first high-κ dielectric layer is deposited directly on the interfacial layer using a deposition technique, such as, but not limited to, ALD, CVD, PVD, MBE, MOCVD, spin-on, radical-assisted doping, or other deposition techniques. In some embodiments, the first high-κ dielectric layer is deposited by ALD.

The first high-κ dielectric layer can have any suitable thickness. In one or more embodiments, the first high-κ dielectric layer has a thickness in a range of about 10 Å to about 20 Å. In one or more embodiments, the first high-κ dielectric layer has a thickness of about 15 Å.

The at least one diffusion barrier layer is deposited directly on the first high-κ dielectric layer using a deposition technique, such as, but not limited to, ALD, CVD, PVD, MBE, MOCVD, spin-on, radical-assisted doping, or other deposition techniques. In some embodiments, the at least one diffusion barrier layer is deposited by ALD.

The at least one diffusion barrier layer can have any suitable thickness. In one or more embodiments, the at least one diffusion barrier layer has a thickness in a range of from about 3 Å to about 25 Å. In one or more embodiments, the at least one diffusion barrier layer has a thickness in a range of about 3 Å to about 20 Å. In one or more embodiments, the at least one diffusion barrier layer has a thickness in a range of about 10 Å to about 20 Å.

In some embodiments, activity 1104 includes forming at least one dipole layer directly on the at least one diffusion barrier layer in each of the plurality of regions.

The at least one dipole layer is deposited directly on the at least one diffusion barrier layer using a deposition technique, such as, but not limited to, ALD, CVD, PVD, MBE, MOCVD, spin-on, radical-assisted doping, or other deposition techniques. In some embodiments, the at least one dipole layer is deposited by ALD.

The at least one dipole layer can have any suitable thickness. In one or more embodiments, the at least one dipole layer has a thickness in a range of about 3 Å to about 25 Å. In one or more embodiments, the at least one dipole layer has a thickness in a range of about 3 Å to about 20 Å. In one or more embodiments, the at least one dipole layer has a thickness in a range of about 10 Å to about 20 Å.

In some embodiments, activity 1106 includes forming at least one capping layer directly on the at least one dipole layer.

The at least one capping layer is deposited directly on the at least one dipole layer using a deposition technique, such as, but not limited to, ALD, CVD, PVD, MBE, MOCVD, spin-on, radical-assisted doping, or other deposition techniques. In some embodiments, the at least one capping layer is deposited by ALD.

The at least one capping layer can have any suitable thickness. In one or more embodiments, the at least one capping layer has a thickness in a range of from about 10 Å to about 20 Å. In one or more embodiments, the at least one capping layer has a thickness of about 15 Å.

In some embodiments, activity 1108 includes performing a first rapid thermal process (RTP) to drive atoms from the at least one dipole layer into an interface between the first high-κ dielectric layer and the interfacial layer in each of the plurality of regions. In some embodiments, the first RTP is an in situ RTP. As used in this context, the “in situ RTP” is performed without a vacuum break. The RTP may be any suitable process known to the skilled artisan. In one or more embodiments, the RTP includes one or more of a spike anneal process, a nanosecond anneal process, or a millisecond anneal process.

In one or more embodiments, the spike anneal process includes exposing the substrate at a temperature of less than or equal to 950° C. in a nitrogen (N₂) ambient environment for 15 seconds. In one or more embodiments, the spike anneal process is performed at a temperature in a range of from 700° C. to 950° C. The RTP may include a nanosecond anneal process (e.g., a flash anneal process) or a millisecond anneal process (e.g., a laser anneal process), as will be understood by the skilled artisan. In one or more embodiments, the nanosecond anneal process and the millisecond anneal process are independently performed at a temperature less than or equal to 1150° C. In one or more embodiments, the first RTP comprises a soak anneal process performed at a temperature in a range of less than or equal to 700° C. for treatment of the first high-κ dielectric layer.

In one or more embodiments, activity 1110 includes removing the at least one capping layer, the at least one dipole layer, and the at least one diffusion barrier layer in each of the plurality of regions to expose a top surface of the first high-κ dielectric layer.

The at least one capping layer, the at least one dipole layer, and/or the at least one diffusion barrier layer can be removed by any suitable etching process, including, but not limited to, the etching processes described herein. In some embodiments, one or more of the at least one capping layer, the at least one dipole layer, or the at least one diffusion barrier layer are removed by the same etching process.

The etching process can be any suitable etching process. In some embodiments, the etching process comprises a wet etch process or a dry etch process. In some embodiments, the etching process comprises a wet etch process. In some embodiments, the wet etch process includes a pre-clean process. In some embodiments, the pre-clean process includes using one or more of ammonium hydroxide (NH₄OH) or water (H₂O). In some embodiments, the water (H₂O) is de-ionized water (DI). In some embodiments, the pre-clean process includes using a ratio of DI:NH₄OH in a range of from 100:1 DI:NH₄OH to 5:1 DI:NH₄OH.

In some embodiments, the pre-clean process includes using a SC-1 solution or a SC-2 solution. In one or more embodiments, the SC-1 solution comprises one or more of ozone, ammonium hydroxide, or hydrogen peroxide. In one or more embodiments, the SC-2 solution comprises one or more of hydrochloric acid or hydrogen peroxide. It has advantageously been found that using a SC-1 solution or a SC-2 solution selectively etches the at least one capping layer, the at least one dipole layer, and/or the at least one diffusion barrier layer, without etching a portion of the interfacial layer and/or the first high-κ dielectric layer.

In some embodiments, activity 1112 includes depositing a second high-κ dielectric layer directly on the top surface of the first high-κ dielectric layer in each of the plurality of regions. In some embodiments, the second high-κ dielectric layer is the same as the first high-κ dielectric layer. In some embodiments, the first high-κ dielectric layer and the second high-κ dielectric layer have different compositions. In some embodiments, the first high-κ dielectric layer and the second high-κ dielectric layer have different thicknesses.

In some embodiments, activity 1114 includes performing a second RTP in each of the plurality of regions. The second RTP can be any suitable RTP, such as the RTP configurations described herein. In some embodiments, the first RTP and the second RTP are the same.

In some embodiments, activity 1116 includes depositing at least one metal gate film directly on the second high-κ dielectric layer in each of the plurality of regions to form multiple threshold voltages (multi-Vₜ) including a different threshold voltage (Vₜ) in each of the plurality of regions of the semiconductor structure.

The at least one metal gate film may be deposited on the substrate by a deposition technique, such as, but not limited to, ALD, CVD, PVD, MBE, MOCVD, spin-on, radical-assisted doping, or other deposition techniques.

The at least one metal gate film can have any suitable thickness. In some embodiments, the at least one metal gate film has a thickness in a range of from greater than or equal to about 1 nm to less than or equal to about 3 nm.

In some embodiments, the one or more processing operations of activity 1118 as part of a standard integration flow to complete fabrication of the respective semiconductor structures, e.g., the semiconductor structure 1200, the semiconductor structure 1300, and/or the semiconductor structure 1400. Those of ordinary skill in the art, with the included description, will be able to implement appropriate functionality without undue experimentation.

In one or more embodiments, the one or more processing operations of activity 1118 includes sequentially performing the following operations: depositing a metal nitride layer directly on the at least one metal gate film, a lithography process, a patterning process, an etching process, a cleaning process, an exposure to a forming gas anneal, and an electrical test.

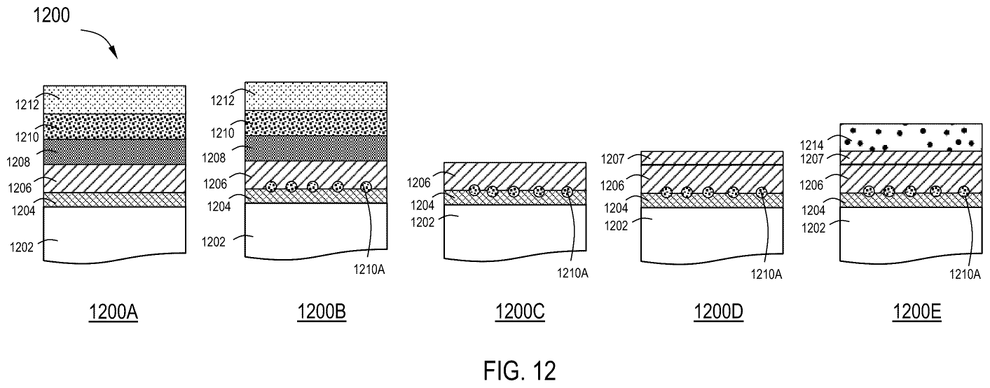

FIGS. 12, 13, and 14 each depict perspective views of a semiconductor structure including a substrate and cross-sectional views of transistors disposed on the substrate, according to some embodiments. In some embodiments, FIGS. 12, 13, and 14 each depict views of semiconductor structures where each respective semiconductor structure has a different threshold voltage (Vₜ). In some embodiments, each respective semiconductor structure, e.g., the semiconductor structure 1200, the semiconductor structure 1300, and the semiconductor structure 1400, each employ diffusion barrier layers having varying thicknesses and/or varying compositions to provide multiple threshold voltages (multi-Vₜ).

FIG. 12 illustrates the semiconductor structure 1200 including a substrate 1202. A first region 1200A, a second region 1200B, a third region 1200C, a fourth region 1200D, and a fifth region 1200E are shown to illustrate various stages processing of the substrate 1202, such as, for example, processing the substrate 1202 in accordance with the method 1100.

The semiconductor structure 1200 comprises, in the first region 1200A, an interfacial layer 1204 directly on the substrate 1202, a first high-κ dielectric layer 1206 directly on the interfacial layer 1204, at least one diffusion barrier layer (e.g., a first diffusion barrier layer 1208) on the first high-κ dielectric layer 1206, at least one dipole layer (e.g., a first dipole layer 1210) directly on the at least one diffusion barrier layer (e.g., the first diffusion barrier layer 1208), and at least one capping layer (e.g., a first capping layer 1212) directly on the at least one dipole layer (e.g., a first dipole layer 1210).

During processing of the substrate 1202, i.e., moving from the first region 1200A to the second region 1200B, a first rapid thermal process (RTP) is performed to drive atoms 1210A from the at least one dipole layer (e.g., the first dipole layer 1210) into an interface between the first high-κ dielectric layer 1206 and the interfacial layer 1204. In one or more embodiments, the atoms 1210A driven into the interface between the first high-κ dielectric layer 1206 and the interfacial layer 1204 are metal atoms from the at least one dipole layer (e.g., the first dipole layer 1210).

During processing of the substrate 1202, i.e., moving from the second region 1200B to the third region 1200C, the at least one capping layer (e.g., a first capping layer 1212), the at least one dipole layer (e.g., the first dipole layer 1210), and the at least one diffusion barrier layer (e.g., the first diffusion barrier layer 1208) are removed to expose a top surface of the first high-κ dielectric layer 1206.

During processing of the substrate 1202, i.e., moving from the third region 1200C to the fourth region 1200D, a second high-κ dielectric layer 1207 is deposited directly on the top surface of the first high-κ dielectric layer 1206.

During processing of the substrate 1202, i.e., moving from fourth region 1200D to the fifth region 1200E, at least one metal gate film 1214 is deposited directly on the second high-κ dielectric layer 1207.

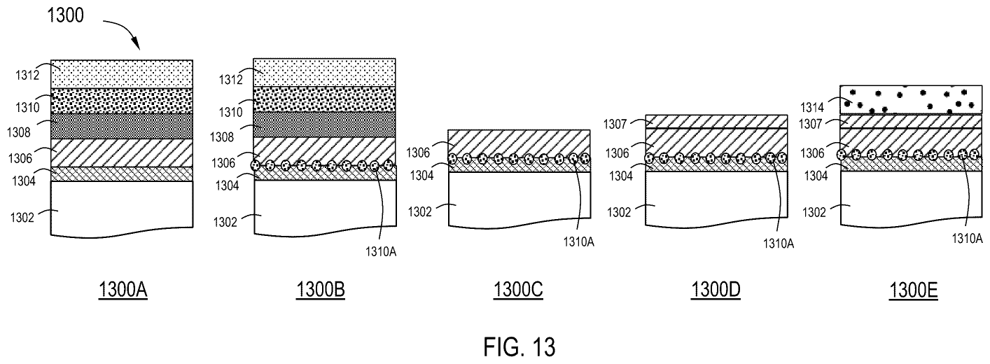

FIG. 13 illustrates the semiconductor structure 1300 including a substrate 1302. A first region 1300A, a second region 1300B, a third region 1300C, a fourth region 1300D, and a fifth region 1300E are shown to illustrate various stages processing of the substrate 1302, such as, for example, processing the substrate 1302 in accordance with the method 1100.

The semiconductor structure 1300 comprises, in the first region 1300A an interfacial layer 1304 directly on the substrate 1302, a first high-κ dielectric layer 1306 directly on the interfacial layer 1304, at least one diffusion barrier layer (e.g., a second diffusion barrier layer 1308) on the first high-κ dielectric layer 1306, at least one dipole layer (e.g., a second dipole layer 1310) directly on the at least one diffusion barrier layer (e.g., the second diffusion barrier layer 1308), and at least one capping layer (e.g., a second capping layer 1312) directly on the at least one dipole layer (e.g., a second dipole layer 1310).

During processing of the substrate 1302, i.e., moving from the first region 1300A to the second region 1300B, a first rapid thermal process (RTP) is performed to drive atoms 1310A from the at least one dipole layer (e.g., the second dipole layer 1310) into an interface between the first high-κ dielectric layer 1306 and the interfacial layer 1304. In one or more embodiments, the atoms 1310A driven into the interface between the first high-κ dielectric layer 1306 and the interfacial layer 1304 are metal atoms from the at least one dipole layer (e.g., the second dipole layer 1310).

During processing of the substrate 1302, i.e., moving from the second region 1300B to the third region 1300C, the at least one capping layer (e.g., a second capping layer 1312), the at least one dipole layer (e.g., the second dipole layer 1310), and the at least one diffusion barrier layer (e.g., the second diffusion barrier layer 1308) are removed to expose a top surface of the first high-κ dielectric layer 1306.

During processing of the substrate 1302, i.e., moving from the third region 1300C to the fourth region 1300D, a second high-κ dielectric layer 1307 is deposited directly on the top surface of the first high-κ dielectric layer 1306.

During processing of the substrate 1302, i.e., moving from fourth region 1300D to the fifth region 1300E, at least one metal gate film 1314 is deposited directly on the second high-κ dielectric layer 1207.

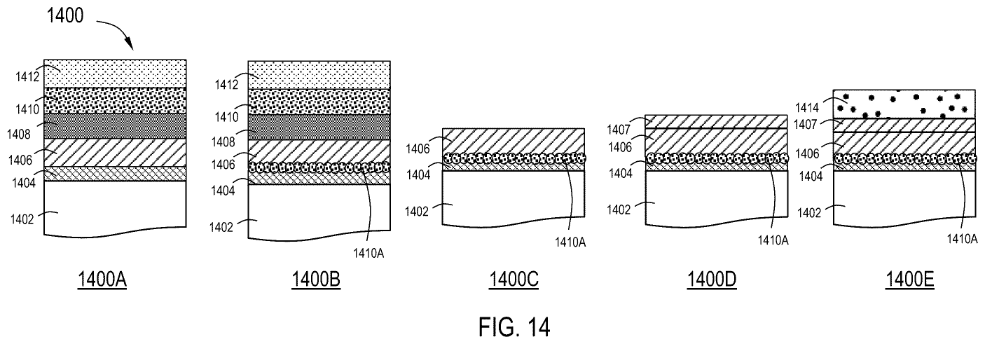

FIG. 14 illustrates the semiconductor structure 1400 including a substrate 1402. A first region 1400A, a second region 1400B, a third region 1400C, a fourth region 1400D, and a fifth region 1400E are shown to illustrate various stages processing of the substrate 1402, such as, for example, processing the substrate 1402 in accordance with the method 1100.

The semiconductor structure 1400 comprises, in the first region 1400A an interfacial layer 1404 directly on the substrate 1402, a first high-κ dielectric layer 1406 directly on the interfacial layer 1404, at least one diffusion barrier layer (e.g., a third diffusion barrier layer 1408) on the first high-κ dielectric layer 1406, at least one dipole layer (e.g., a third dipole layer 1410) directly on the at least one diffusion barrier layer (e.g., the third diffusion barrier layer 1408), and at least one capping layer (e.g., a third capping layer 1412) directly on the at least one dipole layer (e.g., a third dipole layer 1410).

During processing of the substrate 1402, i.e., moving from the first region 1400A to the second region 1400B, a first rapid thermal process (RTP) is performed to drive atoms 1410A from the at least one dipole layer (e.g., the third dipole layer 1410) into an interface between the first high-κ dielectric layer 1406 and the interfacial layer 1404. In one or more embodiments, the atoms 1410A driven into the interface between the first high-κ dielectric layer 1406 and the interfacial layer 1404 are metal atoms from the at least one dipole layer (e.g., the third dipole layer 1410).

During processing of the substrate 1402, i.e., moving from the second region 1400B to the third region 1400C, the at least one capping layer (e.g., a third capping layer 1412), the at least one dipole layer (e.g., the third dipole layer 1410), and the at least one diffusion barrier layer (e.g., the third diffusion barrier layer 1408) are removed to expose a top surface of the first high-dielectric layer 1406.

During processing of the substrate 1402, i.e., moving from the third region 1400C to the fourth region 1400D, a second high-κ dielectric layer 1407 is deposited directly on the top surface of the first high-κ dielectric layer 1406.

During processing of the substrate 1402, i.e., moving from fourth region 1400D to the fifth region 1400E, at least one metal gate film 1414 is deposited directly on the second high-κ dielectric layer 1407.

The substrate 1202, the substrate 1302, and the substrate 1402 may each be independently formed from any substrate material. In some embodiments, one or more of the substrate 1202, the substrate 1302, or the substrate 1402 comprises silicon (Si). In some embodiments, each of the substrate 1202, the substrate 1302, and the substrate 1402 independently comprises silicon (Si).

The interfacial layer 1204, the interfacial layer 1304, and the interfacial layer 1404 may each be independently formed from any suitable dielectric material. In some embodiments, one or more of interfacial layer 1204, the interfacial layer 1304, or the interfacial layer 1404 comprises silicon oxide (SiO₂). In some embodiments, each of the interfacial layer 1204, the interfacial layer 1304, and the interfacial layer 1404 independently comprises silicon oxide (SiO₂).

The first high-κ dielectric layer 1206, the first high-κ dielectric layer 1306, and the first high-κ dielectric layer 1406 may each be independently formed from any suitable high-κ dielectric material. In some embodiments, one or more of the first high-κ dielectric layer 1206, the first high-κ dielectric layer 1306, or the first high-κ dielectric layer 1406 comprises one or more of hafnium oxide (HfOx) (e.g., hafnium oxide (HfO₂)), zirconium oxide (ZrOx), hafnium zirconium (HfZr), or hafnium zirconium oxide (HfZrOx). In some embodiments, each of the first high-κ dielectric layer 1206, the first high-κ dielectric layer 1306, and the first high-κ dielectric layer 1406 independently comprises hafnium oxide (HfO₂).

The first diffusion barrier layer 1208, the second diffusion barrier layer 1308, and the third diffusion barrier layer 1408 may each be independently formed from any suitable metallic material. In some embodiments, one or more of the first diffusion barrier layer 1208, the second diffusion barrier layer 1308, or the third diffusion barrier layer 1408 independently comprises a metal nitride, a metal carbide, a metal silicon nitride, a metal oxide, or combinations thereof. In some embodiments, each of the first diffusion barrier layer 1208, the second diffusion barrier layer 1308, and the third diffusion barrier layer 1408 independently comprises a metal nitride, a metal carbide, a metal silicon nitride, a metal oxide, or combinations thereof.

The metal of each of the metal nitride, the metal carbide, the metal silicon nitride, and the metal oxide can be any suitable metal. In some embodiments, the metal of each of the metal nitride, the metal carbide, the metal silicon nitride, and the metal oxide is selected from the group consisting of aluminum (Al), titanium (Ti), niobium (Nb), tantalum (Ta), hafnium (Hf), and molybdenum (Mo).

In some embodiments, one or more of the first diffusion barrier layer 1208, the second diffusion barrier layer 1308, or the third diffusion barrier layer 1408 independently comprises aluminum nitride (AlN), aluminum carbide (AlC), aluminum silicon nitride (AlSiN), aluminum oxide (AlOx), titanium nitride (TIN), titanium carbide (TiC), titanium silicon nitride (TiSiN), titanium oxide (TiOx), niobium nitride (NbN), niobium carbide (NbC), niobium silicon nitride (NbSiN), niobium oxide (NbOx), tantalum nitride (TaN), tantalum carbide (TaC), tantalum silicon nitride (TaSiN), tantalum oxide (TaOx), hafnium nitride (HfN), hafnium carbide, hafnium silicon nitride (HfSiN), hafnium oxide (HfOx), molybdenum nitride (MoN), molybdenum carbide (MoC), molybdenum silicon nitride (MoSiN), molybdenum oxide (MoOx), or combinations thereof.

In some embodiments, one or more of the first diffusion barrier layer 1208, the second diffusion barrier layer 1308, or the third diffusion barrier layer 1408 are composed of different materials from one another, where each of the first diffusion barrier layer 1208, the second diffusion barrier layer 1308, and the third diffusion barrier layer 1408 independently comprises a metal nitride, a metal carbide, a metal silicon nitride, a metal oxide, or combinations thereof. In some embodiments, each of the first diffusion barrier layer 1208, the second diffusion barrier layer 1308, and the third diffusion barrier layer 1408 are composed of different materials from one another, where each of the first diffusion barrier layer 1208, the second diffusion barrier layer 1308, and the third diffusion barrier layer 1408 independently comprises a metal nitride, a metal carbide, a metal silicon nitride, a metal oxide, or combinations thereof.

The first dipole layer 1210, the second dipole layer 1310, and the third dipole layer 1410 may each be independently formed from any suitable metallic material. In some embodiments, one or more of the first dipole layer 1210, the second dipole layer 1310, or the third dipole layer 1410 comprises at least one n-type dipole layer or at least one p-type dipole layer, without limitation. In some embodiments, each of the first dipole layer 1210, the second dipole layer 1310, and the third dipole layer 1410 comprises at least one n-type dipole layer or at least one p-type dipole layer.

The first capping layer 1212, the second capping layer 1312, and the third capping layer 1412 may each be independently formed from any suitable metallic material. In some embodiments, one or more of the first capping layer 1212, the second capping layer 1312, or the third capping layer 1412 independently comprises a metal nitride, a metal carbide, a metal silicon nitride, a metal oxide, a metalloid nitride, a metalloid carbide, or combinations thereof. In some embodiments, each of the first capping layer 1212, the second capping layer 1312, and the third capping layer 1412 independently comprises a metal nitride, a metal carbide, a metal silicon nitride, a metal oxide, a metalloid nitride, a metalloid carbide, or combinations thereof.

The metal of each of the metal nitride, the metal carbide, the metal silicon nitride, and the metal oxide can be any suitable metal. In some embodiments, the metal of each of the metal nitride, the metal carbide, the metal silicon nitride, and the metal oxide is selected from the group consisting of aluminum (Al), titanium (Ti), niobium (Nb), tantalum (Ta), hafnium (Hf), and molybdenum (Mo).

The metalloid of each of the metalloid nitride and the metalloid carbide can be any suitable metalloid. In some embodiments, the metalloid of each of the metalloid nitride and the metalloid carbide is selected from the group consisting of boron (B), silicon (Si), germanium (Ge), antimony (Sb), and tellurium (Te).

In some embodiments, one or more of the first capping layer 1212, the second capping layer 1312, or the third capping layer 1412 independently comprises aluminum nitride (AlN), aluminum carbide (AlC), aluminum silicon nitride (AlSiN), aluminum oxide (AlOx), titanium nitride (TiN), titanium carbide (TIC), titanium silicon nitride (TiSiN), titanium oxide (TiOx), niobium nitride (NbN), niobium carbide (NbC), niobium silicon nitride (NbSiN), niobium oxide (NbOx), tantalum nitride (TaN), tantalum carbide (TaC), tantalum silicon nitride (TaSiN), tantalum oxide (TaOx), hafnium nitride (HfN), hafnium carbide, hafnium silicon nitride (HfSiN), hafnium oxide (HfOx), molybdenum nitride (MON), molybdenum carbide (MoC), molybdenum silicon nitride (MoSiN), molybdenum oxide (MoOx), boron nitride (BN), boron carbide (BC), silicon nitride (SiN), silicon carbide (SIC), or combinations thereof.

In some embodiments, one or more of the first capping layer 1212, the second capping layer 1312, or the third capping layer 1412 are composed of different materials from one another, where each of the first capping layer 1212, the second capping layer 1312, and the third capping layer 1412 independently comprises a metal nitride, a metal carbide, a metal silicon nitride, a metal oxide, a metalloid nitride, a metalloid carbide, or combinations thereof.

In some embodiments, each of the first diffusion barrier layer 1208, the second diffusion barrier layer 1308, and the third diffusion barrier layer 1408 are composed of different materials from one another, where each of the first diffusion barrier layer 1208, the second diffusion barrier layer 1308, and the third diffusion barrier layer 1408 independently comprises a metal nitride, a metal carbide, a metal silicon nitride, a metal oxide, a metalloid nitride, a metalloid carbide, or combinations thereof.

The second high-κ dielectric layer 1207, the second high-κ dielectric layer 1307, and the second high-κ dielectric layer 1407 may each be independently formed from any suitable high-κ dielectric material. In some embodiments, one or more of the second high-κ dielectric layer 1207, the second high-κ dielectric layer 1307, or the second high-κ dielectric layer 1407 are composed of the same material as one or more of the first high-κ dielectric layer 1206, the first high-κ dielectric layer 1306, or the first high-κ dielectric layer 1406.

In some embodiments, one or more of the second high-κ dielectric layer 1207, the second high-κ dielectric layer 1307, or the second high-κ dielectric layer 1407 comprises one or more of hafnium oxide (HfOx) (e.g., hafnium oxide (HfO₂)), zirconium oxide (ZrOx), hafnium zirconium (HfZr), or hafnium zirconium oxide (HfZrOx). In some embodiments, each of second high-κ dielectric layer 1207, the second high-κ dielectric layer 1307, and the second high-κ dielectric layer 1407 independently comprises hafnium oxide (HfO₂).

The at least one metal gate film 1214, the at least one metal gate film 1314, and the at least one metal gate film 1414 each independently comprise one or more N-metal gate films and/or one or more P-metal gate films.

In some embodiments, the at least one metal gate film 1214, the at least one metal gate film 1314, and the at least one metal gate film 1414 each independently includes one or more P-metal gate films, and each of the one or more P-metal gate films independently has a formula of MXN, where M is a first metal selected from the group consisting of hafnium (Hf), magnesium (Mg), lanthanum (La), yttrium (Y), aluminum (Al), manganese (Mn), zirconium (Zr), tantalum (Ta), vanadium (V), zinc (Zn), titanium (Ti), niobium (Nb), tin (Sn), tungsten (W), molybdenum (Mo), ruthenium (Ru), and antimony (Sb), X is a second metal selected from the group consisting of hafnium (Hf), magnesium (Mg), lanthanum (La), yttrium (Y), aluminum (Al), manganese (Mn), zirconium (Zr), tantalum (Ta), vanadium (V), zinc (Zn), titanium (Ti), niobium (Nb), tin (Sn), tungsten (W), molybdenum (Mo), ruthenium (Ru), and antimony (Sb), the second metal is different from the first metal, and N is nitrogen.

The first metal M and the second metal X can be present in the formula of MXN in any suitable amount in at. %. In some embodiments, X is in a range of from 0 at. % to 40 at. %.

In some embodiments, the at least one metal gate film 1214, the at least one metal gate film 1314, and the at least one metal gate film 1414 each independently includes one or more N-metal gate films, and each of the one or more N-metal gate films independently comprises titanium (Ti), tantalum (Ta), aluminum (Al), lanthanum (La), zirconium (Zr), scandium (Sc), yttrium (Y), ytterbium (Yb), carbon (C), silicon (Si), or combinations thereof.

In some embodiments, the at least one metal gate film 1214, the at least one metal gate film 1314, and the at least one metal gate film 1414 each independently includes one or more N-metal gate films, and each of the one or more N-metal gate films independently comprises one or more of titanium silicide (TiSi), tantalum silicide (TaSi), aluminum silicide (AlSi), lanthanum silicide (LaSi), zirconium silicide (ZrSi), yttrium silicide (YSi), ytterbium silicide (YbSi), scandium silicide (ScSi), or lanthanum silicide (LaSi).

In some embodiments, the at least one metal gate film 1214, the at least one metal gate film 1314, and the at least one metal gate film 1414 each independently includes one or more N-metal gate films, and each of the one or more N-metal gate films independently comprises one or more of titanium carbide (TiC), tantalum carbide (TaC), aluminum carbide (AlC), lanthanum carbide (LaC), zirconium carbide (ZrC), yttrium carbide (YC), ytterbium carbide (YbC), scandium carbide (ScC), or lanthanum carbide (LaC).

In some embodiments, the at least one metal gate film 1214, the at least one metal gate film 1314, and the at least one metal gate film 1414 each independently includes one or more N-metal gate films, and each of the one or more N-metal gate films independently comprises one or more of titanium aluminum carbide (TiAlC), titanium aluminum silicide (TiAlSi), tantalum aluminum carbide (TaAlC), tantalum aluminum silicide (TaAlSi), zirconium carbide (ZrC), yttrium carbide (YC), ytterbium carbide (YbC), scandium carbide (ScC), lanthanum carbide (LaC), zirconium aluminum silicide (ZrAlSi), yttrium aluminum silicide (YAlSi), ytterbium aluminum silicide (YbAlSi), scandium aluminum silicide (ScAlSi), lanthanum aluminum silicide (LaAlSi), zirconium aluminum carbide (ZrAlC), yttrium aluminum carbide (YAlC), ytterbium aluminum carbide (YbAlC), scandium aluminum carbide (ScAlC), or lanthanum aluminum carbide (LaAlC).

To avoid silicon scavenging, a thin layer (less than or equal to 6 Å) of metal nitride (such as, for example, titanium nitride (TiN)) may be deposited below the at least one metal gate film 1214, the at least one metal gate film 1314, and/or the at least one metal gate film 1414). Stated differently, the thin layer of metal nitride may be deposited directly on the top surface of the second high-κ dielectric layer 1207, the second high-κ dielectric layer 1307, and/or the second high-κ dielectric layer 1407, and the at least one metal gate film 1214, the at least one metal gate film 1314, and/or the at least one metal gate film 1414 may be deposited directly on the thin layer of metal nitride.

After depositing the at least one metal gate film on or directly on the top surface of the second high-κ dielectric layer 1207, the second high-κ dielectric layer 1307, and/or the second high-κ dielectric layer 1407, the method 1100 optionally includes one or more processing operations (activity 1118).

In some embodiments, the one or more processing operations of activity 1118 as part of a standard integration flow to complete fabrication of the respective semiconductor structures, e.g., the semiconductor structure 1200, the semiconductor structure 1300, and/or the semiconductor structure 1400. Those of ordinary skill in the art, with the included description, will be able to implement appropriate functionality without undue experimentation.

In one or more embodiments, the one or more processing operations of activity 1118 includes sequentially performing the following operations: depositing a metal nitride layer directly on the at least one metal gate film, a lithography process, a patterning process, an etching process, a cleaning process, an exposure to a forming gas anneal, and an electrical test.

In some embodiments, the semiconductor structure 1200, the semiconductor structure 1300, and/or the semiconductor structure 1400 is a PFET device. In some embodiments, the semiconductor structure 1200, the semiconductor structure 1300, and/or the semiconductor structure 1400 is an NFET device.

In some embodiments, the semiconductor structure 1200 has a first threshold voltage (Vₜ) value. In some embodiments, the semiconductor structure 1300 has a second threshold voltage (Vₜ) value. In some embodiments, the semiconductor structure 1400 has a third threshold voltage (Vₜ) value. In some embodiments, one or more of the first threshold voltage (Vₜ) value, the second threshold voltage (Vₜ) value, and the third threshold voltage (Vₜ) value are different from one another.

In some embodiments, one or more of the first threshold voltage (Vₜ) value, the second threshold voltage (Vₜ) value, and the third threshold voltage (Vₜ) value are different from one another based upon varying thicknesses of the respective diffusion barrier layer, i.e., the first diffusion barrier layer 1208, the second diffusion barrier layer 1308, and the third diffusion barrier layer 1408. In some embodiments, each of the first diffusion barrier layer 1208, the second diffusion barrier layer 1308, and the third diffusion barrier layer 1408 have a thickness in a range of 3 Å to 25 Å, and each of the first diffusion barrier layer 1208, the second diffusion barrier layer 1308, and the third diffusion barrier layer 1408 have a different thickness within the range of 3 Å to 25 Å.

In some embodiments, one or more of the first threshold voltage (Vₜ) value, the second threshold voltage (Vₜ) value, and the third threshold voltage (Vₜ) value are different from one another based upon varying compositions of the respective diffusion barrier layer, i.e., the first diffusion barrier layer 1208, the second diffusion barrier layer 1308, and the third diffusion barrier layer 1408. In some embodiments, each of the first diffusion barrier layer 1208, the second diffusion barrier layer 1308, and the third diffusion barrier layer 1408 have a different composition.

The methods described herein can be performed in any suitable processing system. In one or more embodiments, each of the operations of the methods described herein are performed in situ in an integrated processing system. In one or more embodiments, one or more of the operations of the methods described herein are performed ex situ. The particular arrangement of processing chambers and components can be varied depending on the processing system and should not be taken as limiting the scope of the disclosure.

Embodiments of the disclosure are directed to a non-transitory computer readable medium. In one or more embodiments, the non-transitory computer readable medium includes instructions that, when executed by a controller of a processing system, causes the processing system to perform the operations of any of the processes described herein.

While the foregoing is directed to implementations of the present disclosure, other and further implementations of the present disclosure may be devised without departing from the basic scope thereof, and the scope thereof is determined by the claims that follow.

What is claimed is:

1. A method comprising:
forming at least one diffusion barrier layer directly on a first high-κ dielectric layer directly on an interfacial layer of a semiconductor structure having a plurality of regions;
forming at least one dipole layer directly on the at least one diffusion barrier layer in each of the plurality of regions;
forming at least one capping layer directly on the at least one dipole layer;
performing a first rapid thermal process (RTP) to drive atoms from the at least one dipole layer into an interface between the first high-κ dielectric layer and the interfacial layer in each of the plurality of regions;
removing the at least one capping layer, the at least one dipole layer, and the at least one diffusion barrier layer in each of the plurality of regions to expose a top surface of the first high-κ dielectric layer;
depositing a second high-κ dielectric layer directly on the top surface of the first high-κ dielectric layer in each of the plurality of regions;
performing a second RTP in each of the plurality of regions; and
depositing at least one metal gate film directly on the second high-κ dielectric layer in each of the plurality of regions to form multiple threshold voltages (multi-Vₜ) including a different threshold voltage (Vₜ) in each of the plurality of regions of the semiconductor structure.

2. The method of claim 1, wherein the interfacial layer comprises silicon oxide (SiO₂).

3. The method of claim 1, wherein each of the first high-κ dielectric layer and the second high-κ dielectric layer independently comprises one or more of hafnium oxide (HfOx), zirconium oxide (ZrOx), hafnium zirconium (HfZr), or hafnium zirconium oxide (HfZrOx).

4. The method of claim 1, wherein each of the at least one diffusion barrier layer independently comprises a metal nitride, a metal carbide, a metal silicon nitride, a metal oxide, or combinations thereof.

5. The method of claim 4, wherein each of the at least one diffusion barrier layer is different.

6. The method of claim 4, wherein the metal of each of the metal nitride, the metal carbide, the metal silicon nitride, and the metal oxide is selected from the group consisting of aluminum (Al), titanium (Ti), niobium (Nb), tantalum (Ta), hafnium (Hf), and molybdenum (Mo).

7. The method of claim 4, wherein each of the at least one diffusion barrier layer independently has a different thickness.

8. The method of claim 1, wherein each of the at least one capping layer independently comprises a metal nitride, a metal carbide, a metal silicon nitride, a metal oxide, a metalloid nitride, a metalloid carbide, or combinations thereof.

9. The method of claim 8, wherein each of the at least one capping layer is different.

10. The method of claim 8, wherein the metal of each of the metal nitride, the metal carbide, the metal silicon nitride, and the metal oxide is selected from the group consisting of aluminum (Al), titanium (Ti), niobium (Nb), tantalum (Ta), hafnium (Hf), and molybdenum (Mo).

11. The method of claim 8, wherein the metalloid of each of the metalloid nitride and the metalloid carbide is selected from the group consisting of boron (B), silicon (Si), germanium (Ge), antimony (Sb), and tellurium (Te).

12. The method of claim 1, wherein each of the first RTP and the second RTP are independently performed at a temperature of less than or equal to 1150° C.

13. The method of claim 12, wherein each of the first RTP and the second RTP independently include one or more of a spike anneal process, a nanosecond anneal process, or a millisecond anneal process.

14. The method of claim 1, wherein each of the at least one metal gate film independently comprises one or more N-metal gate films and/or one or more P-metal gate films.

15. A method comprising:
forming a first diffusion barrier layer directly on a first high-κ dielectric layer directly on an interfacial layer of a semiconductor structure having a first region, a second region, and a third region, the first diffusion barrier layer formed on the first region;
forming a first dipole layer directly on the first diffusion barrier layer;
forming a first capping layer directly on the first dipole layer;
performing a first rapid thermal process (RTP) to drive atoms from the first dipole layer into an interface between the first high-κ dielectric layer and the interfacial layer in the first region;
removing the first capping layer, the first dipole layer, and the first diffusion barrier layer in the first region to expose a top surface of the first high-κ dielectric layer;
depositing a second high-κ dielectric layer directly on the top surface of the first high-κ dielectric layer in the first region;
performing a second RTP; and
depositing at least one metal gate film directly on the second high-κ dielectric layer to form a first threshold voltage (Vₜ) in the first region.

16. The method of claim 15, further comprising:
forming a second diffusion barrier directly on the first high-κ dielectric layer in the second region;
forming a second dipole layer directly on the second diffusion barrier layer;
forming a second capping layer directly on the second dipole layer;
performing a first rapid thermal process (RTP) to drive atoms from the second dipole layer into an interface between the first high-κ dielectric layer and the interfacial layer in the second region;
removing the second capping layer, the second dipole layer, and the second diffusion barrier layer in the second region to expose a top surface of the first high-κ dielectric layer;
depositing a second high-κ dielectric layer directly on the top surface of the first high-κ dielectric layer in the second region;
performing a second RTP; and
depositing at least one metal gate film directly on the second high-κ dielectric layer to form a second threshold voltage (Vₜ) in the second region.

17. The method of claim 16, further comprising:
forming a third diffusion barrier directly on the first high-κ dielectric layer in the third region;
forming a third dipole layer directly on the third diffusion barrier layer;
forming a third capping layer directly on the third dipole layer;
performing a first rapid thermal process (RTP) to drive atoms from the third dipole layer into an interface between the first high-κ dielectric layer and the interfacial layer in the third region;
removing the third capping layer, the third dipole layer, and the third diffusion barrier layer in the third region to expose a top surface of the first high-κ dielectric layer;
depositing a second high-κ dielectric layer directly on the top surface of the first high-κ dielectric layer in the third region;
performing a second RTP; and
depositing at least one metal gate film directly on the second high-κ dielectric layer to form a third threshold voltage (Vₜ) in the third region.

18. The method of claim 17, wherein the first diffusion barrier layer has a first thickness, the second diffusion barrier layer has a second thickness, and the third diffusion barrier layer has a third thickness, and each of the first thickness, the second thickness, and the third thickness are different.

19. The method of claim 17, wherein each of the first dipole layer, the second dipole layer, and the third dipole layer independent comprise an n-type dipole layer or a p-type dipole layer.

20. A processing system comprising:
a first transfer module and a second transfer module, each of the first transfer module and the second transfer module independently comprising a substrate handling robot configured to move at least one substrate;
a plurality of process chambers, wherein the substrate handling robot of the first transfer module is configured to transfer the at least one substrate between some of the process chambers and the substrate handling robot of the second transfer module is configured to transfer the at least one substrate between some of the process chambers; and
a system controller configured to process the at least one substrate, and the system controller configured to perform a method comprising:
forming at least one diffusion barrier layer directly on a first high-κ dielectric layer directly on an interfacial layer of a semiconductor structure having a plurality of regions;
forming at least one dipole layer directly on the at least one diffusion barrier layer in each of the plurality of regions;
forming at least one capping layer directly on the at least one dipole layer;
performing a first rapid thermal process (RTP) to drive atoms from the at least one dipole layer into an interface between the first high-κ dielectric layer and the interfacial layer in each of the plurality of regions;
removing the at least one capping layer, the at least one dipole layer, and the first diffusion barrier layer in each of the plurality of regions to expose a top surface of the first high-κ dielectric layer;
depositing a second high-κ dielectric layer directly on the top surface of the first high-κ dielectric layer in each of the plurality of regions;
performing a second RTP in each of the plurality of regions; and
depositing at least one metal gate film directly on the second high-κ dielectric layer in each of the plurality of regions to form multiple threshold voltages (multi-Vₜ) including a different threshold voltage (Vₜ) in each of the plurality of regions of the semiconductor structure.
